(19) United States
(12) Patent Application Publication
(10) Pub. No.: US 2025/0380413 A1
(43) Pub. Date: Dec. 11, 2025

(54) SEMICONDUCTOR DEVICE AND METHOD FOR MANUFACTURING THE SAME

(71) Applicant: MACRONIX INTERNATIONAL CO., LTD., Hsinchu (TW)

(72) Inventors: Erh-Kun LAI, Taichung County (TW); Feng-Min LEE, Hsinchu City (TW)

(21) Appl. No.: 18/739,526

(22) Filed: Jun. 11, 2024

(51) Int. Cl. H10B 43/27; H01L 23/00; H01L 25/00; H01L 25/065; H01L 25/18; H10B 80/00

(52) U.S. Cl. CPC H10B 43/27; H01L 24/08; H01L 24/80; H01L 25/0657; H01L 25/18; H01L 25/50; H10B 80/00; H01L 2224/08145; H01L 2224/80895; H01L 2224/80896; H01L 2924/1431; H01L 2924/14511

(57) ABSTRACT

A semiconductor device and a method for manufacturing the same are provided. The semiconductor device includes a substrate, a stack structure on the substrate, an interconnection structure between the substrate and the stack structure, and a pillar element penetrating the stack structure. The pillar element includes a channel layer, a memory layer surrounding the channel layer, and a dielectric layer surrounding the channel layer. The dielectric layer and the memory layer include different materials.

### BACKGROUND

### Technical Field

The disclosure relates to a semiconductor device and a method for manufacturing the same, and more particularly to a three-dimensional semiconductor device and a method for manufacturing the same.

### Description of the Related Art

In the semiconductor technology, shrinking of feature sizes, and improving operation speed, efficiency, density, and cost per Integrated circuit are important objectives. However, as the size of semiconductor devices shrinks, the reduced distance between elements may cause undesirable disturbance problems, resulting in reduced electrical performance of the semiconductor device.

### SUMMARY

According to embodiments of the present disclosure, a semiconductor device is provided. The semiconductor device includes a substrate, a stack structure on the substrate, an interconnection structure between the substrate and the stack structure, and a pillar element penetrating the stack structure. The pillar element includes a channel layer, a memory layer surrounding the channel layer, and a dielectric layer surrounding the channel layer. The dielectric layer and the memory layer include different materials.

According to embodiments of the present disclosure, a method for manufacturing semiconductor device is provided. The method includes: forming a stack structure on a substrate; forming a channel layer penetrating the stack structure; forming an interconnection structure on a first surface of the stack structure; forming a memory layer penetrating the stack structure and surrounding the channel layer; forming a dielectric layer on a sidewall of the channel layer, wherein the dielectric layer and the memory layer include different materials; forming a conductive film on a second surface of the stack structure, wherein the second surface is opposite to the first surface.

The above and other embodiments of the disclosure will become better understood with regard to the following detailed description of the non-limiting embodiment(s). The following description is made with reference to the accompanying drawings.

### BRIEF DESCRIPTION OF THE DRAWINGS

FIG. 1 illustrates a schematic cross-sectional view of a semiconductor device according to some embodiments of the present disclosure.

FIG. 2 illustrates a schematic cross-sectional view of a semiconductor device according to some embodiments of the present disclosure.

FIG. 3 to FIG. 22 illustrate schematic cross-sectional views of various stages of a method for manufacturing a semiconductor device according to some embodiments of the present disclosure.

FIG. 23 to FIG. 36 illustrate schematic cross-sectional views of various stages of a method for manufacturing a semiconductor device according to some embodiments of the present disclosure.

### DETAILED DESCRIPTION

Various embodiments will be described more fully hereinafter with reference to accompanying drawings, which are provided for illustrative and explaining purposes rather than a limiting purpose. For clarity, the components may not be drawn to scale. In addition, some components and/or reference numerals may be omitted from some drawings. It is contemplated that the elements and features of one embodiment can be beneficially incorporated in another embodiment without further recitation. In the following methods for manufacturing semiconductor devices, there may be one or more additional operations between the operations described, and the order of the operations may vary. The illustration uses the same/similar reference numerals to indicate the same/similar elements.

As used in the specification and the appended claims, the ordinals such as “first”, “second” and the like to describe elements do not imply or represent a specific position in the structure, or the order of arrangement, or the order of manufacturing. The ordinals are only used to clearly distinguish multiple elements with the same name. As used in the specification and the appended claims, spatial relation terms such as “on”, “above”, “over”, “upper,” “top”, “below”, “beneath”, “under”, “lower”, “bottom” and the like may be used to describe the relative spatial relations or positional relations between one element(s) and another element(s) as illustrated in the drawings, and these spatial relations or positional relations, unless specified otherwise, can be direct or indirect. The spatial relation terms are intended to encompass different orientations of structures in addition to the orientation depicted in the drawings. The structure can be inverted or rotated by various angles, and the spatial relation descriptions used herein can be interpreted accordingly. As used in the specification and the appended claims, the singular forms “a,” “an,” and “the” are intended to include the plural forms as well, unless the context clearly indicates otherwise. As used in the specification and the appended claims, the term “and/or” includes any and all combinations of one or more of the associated listed items.

Additionally, the term “electrically connected” used in the specification and claims can refer to an ohmic contact between elements, or current passing through elements, or an operational relation between elements. The operational relation may mean, for example, that one element is used to drive another element, but current may not flow directly between these two elements. As used in the specification and the appended claims, term “deposition” includes, but is not limited to, chemical vapor deposition (CVD), physical vapor deposition (PVD), atomic layer deposition (ALD) and epitaxial growth. Depending on the type of material to be formed, a person of ordinary skill in the art can select an appropriate technology for forming the material. As used in the specification and the appended claims, terms “etching”, “etching back” and “selectively etching” include, but are not limited to, dry etching and wet etching. As used in the specification and the appended claims, term “polishing process” includes, but is not limited to, a chemical-mechanical planarization (CMP) and an ion milling process. The terms “etching”, “etching back” and “polishing process” used in the specification and the appended claims may replace with each other, and a person of ordinary skill in the art can select an appropriate removal technology depending on the structure and material.

Embodiments according to the present disclosure can be applied to many different types of three-dimensional semiconductor structures. For example, the embodiments can be applied to, but not limited to, three-dimensional semiconductor devices. For example, embodiments of the present disclosure may be applied to, but are not limited to, semiconductor devices including memory array; the memory array may be a volatile memory array or a non-volatile memory array. In some embodiments, the present disclosure can be applied to semiconductor devices including vertical channel NAND type flash memories.

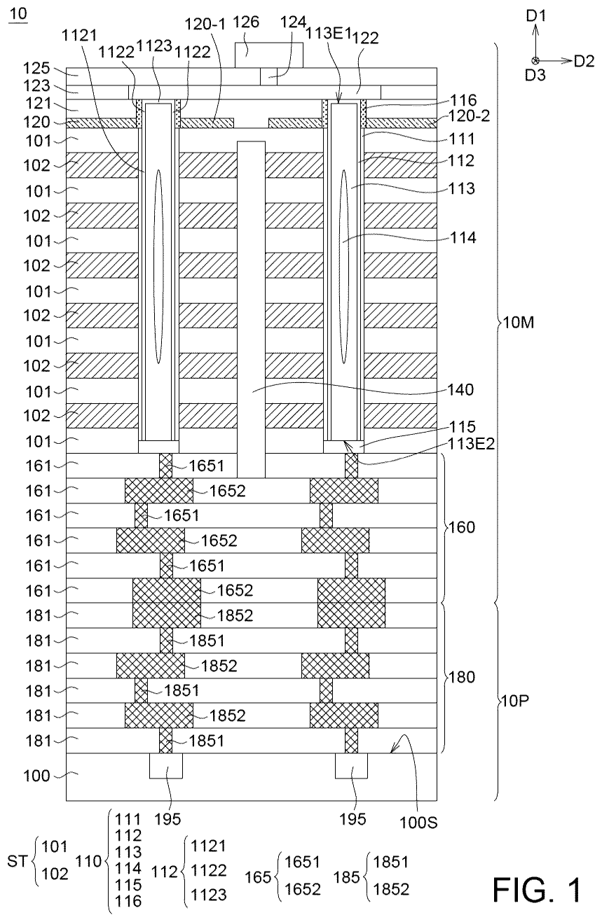

FIG. 1 illustrates a schematic cross-sectional view of a semiconductor device 10 according to some embodiments of the present disclosure. The semiconductor device 10 includes a semiconductor structure 10P and a semiconductor structure 10M. The semiconductor structure 10P is bonded to the semiconductor structure 10M.

The semiconductor structure 10P includes a substrate 100, one or more semiconductor elements 195 in the substrate 100, and an interconnection structure 180 on the substrate 100. The interconnection structure 180 may include one or more insulating material layers 181 and one or more conductive interconnections 185 in the one or more insulating material layers 181. The conductive interconnection 185 may be electrically connected to the semiconductor element 195. In some embodiment, the conductive interconnections 185 are separated from each other by the insulating material layers 181. In the present embodiment, the insulating material layers 181 are stacked along a first direction D1. The first direction D1 can be parallel or substantially parallel to the normal direction of the upper surface 100S of the substrate 100. The conductive interconnection 185 includes one or more via elements 1851 and one or more conductive elements 1852. FIG. 1 shows that the conductive interconnection 185 includes three via elements 1851 and three conductive elements 1852, but the present disclosure is not limited thereto. The conductive interconnection 185 may include more or less via elements 1851 and more or less conductive elements 1852. The via element 1851 is electrically connected to the conductive element 1852. The semiconductor element 195 can be a peripheral device. The peripheral device can be used to control the signals transmitted to or from the semiconductor structure 10M. The peripheral device may include digital peripheral circuits, analog peripheral circuits, and/or mixed-signal peripheral circuits. For example, the peripheral device may include a page buffer, a row decoder, a column decoder, a sense amplifier, a driver, a transistor, a diode, a resistor, or a capacitor. FIG. 1 shows that the semiconductor element 195 is in the substrate 100, but the present disclosure is not limited thereto. The semiconductor element 195 can be formed on the upper surface 100S of the substrate 100, or partially formed in the substrate 100 (i.e. a portion of the semiconductor element 195 is above the upper surface 100S of the substrate 100 and another portion of the semiconductor element 195 is below the upper surface 100S of the substrate 100), or completely formed in the substrate 100 (i.e. the semiconductor element 195 is completely below the upper surface 100S of the substrate 100). In some embodiments, the semiconductor structure 10P may include one or more isolation regions between the semiconductor elements 195 to separate the semiconductor elements 195 from each other. In some embodiments, the semiconductor element 195 is formed in the substrate 100 or on the substrate 100 using a complementary metal-oxide-semiconductor (complementary metal-oxide-semiconductor; CMOS) technology.

The semiconductor structure 10M includes an interconnection structure 160, a stack structure ST, a pillar element 110, an isolation layer 140, a conductive film 120, a conductive structure 122, a via element 124, a conductive element 126, an insulating material layer 121, an insulating material layer 123 and an insulating material layer 125. The interconnection structure 160 is on the interconnection structure 180 and bonded to the interconnection structure 180. The interconnection structure 160 may include one or more insulating material layers 161 and one or more conductive interconnections 165 in the one or more insulating material layers 161. In some embodiment, the conductive interconnections 165 are separated from each other by the insulating material layers 161. In the present embodiment, the insulating material layers 161 are stacked along a first direction D1. The conductive interconnection 165 includes one or more via elements 1651 and one or more conductive elements 1652. FIG. 1 shows that the conductive interconnection 165 includes three via elements 1651 and three conductive elements 1652, but the present disclosure is not limited thereto. The conductive interconnection 165 may include more or less via elements 1651 and more or less conductive elements 1652. The via element 1651 is electrically connected to the conductive element 1652. The insulating material layers 161 of the interconnection structure 160 can be bonded to the insulating material layers 181 of the interconnection structure 180. The conductive elements 1652 of the interconnection structure 160 can be bonded to the conductive elements 1852 of the interconnection structure 180. The conductive interconnection 165 can be electrically connected to the conductive interconnection 185.

The stack structure ST is on the substrate 100. The interconnection structure 160 and the interconnection structure 180 are between the substrate 100 and the stack structure ST. The stack structure ST includes insulating layers 101 and conductive layers 102 stacked alternately along the first direction D1. The conductive layers 102 are separated from each other by the insulating layers 101. In the present embodiment, the uppermost layer and the lowermost layer of the stack structure ST are both insulating layers 101. The lowermost insulating layer 101 can directly contact the insulating material layer 161 of the interconnection structure 160. FIG. 1 shows seven insulating layers 101 and six conductive layers 102, but the present disclosure is not limited thereto. The stack structure ST may include more or less insulating layers 101 and more or less conductive layers 102.

The semiconductor structure 10M may include one or more pillar elements 110. The pillar elements 110 can be separated from each other. The pillar element 110 extends along the first direction D1 and penetrates the stack structure ST. The pillar element 110 includes a memory layer 111, a channel layer 112, an insulating film 113, an air gap 114, a pad 115 and a dielectric layer 116. The conductive layers 102 of the stack structure ST may surround the memory layer 111. The channel layer 112 and the insulating film 113 extend beyond the stack structure ST. The memory layer 111 and the pad 115 are in the stack structure ST. The dielectric layer 116 is on the stack structure ST. The channel layer 112 includes a first channel portion 1121, a second channel portion 1122 and a third channel portion 1123. The second channel portion 1122 is connected between the first channel portion 1121 and the third channel portion 1123. The first channel portion 1121 is between the insulating film 113 and the memory layer 111. The memory layer 111 is on the outer sidewall of the first channel portion 1121 of the channel layer 112. The memory layer 111 may cover the outer sidewall of the first channel portion 1121. The memory layer 111 may surround the first channel portion 1121. The memory layer 111 may have a tubular shape. The first channel portion 1121 is on the sidewall of the insulating film 113. The first channel portion 1121 may surround a portion of the sidewall of the insulating film 113. The second channel portion 1122 is between the insulating film 113 and the dielectric layer 116. The dielectric layer 116 is on the outer sidewall of the second channel portion 1122 of the channel layer 112. The dielectric layer 116 may cover the outer sidewall of the second channel portion 1122. The dielectric layer 116 may surround the second channel portion 1122. The dielectric layer 116 may have a tubular shape. The second channel portion 1122 is on the sidewall of the insulating film 113. The second channel portion 1122 may surround a portion of the sidewall of the insulating film 113. The third channel portion 1123 is between the insulating film 113 and the conductive structure 122. The third channel portion 1123 may be on an end portion 113E1 of the insulating film 113. The third channel portion 1123 may cover the end portion 113E1 of the insulating film 113. The insulating film 113 extends along the first direction D1 and penetrates the stack structure ST. The air gap 114 is in the insulating film 113. The pad 115 is on an end portion 113E2 of the insulating film 113. The end portion 113E1 and the end portion 113E2 of the insulating film 113 are on opposite sides of the insulating film 113. The pad 115 is between the insulating film 113 and the interconnection structure 160. The memory layer 111 is connected between the dielectric layer 116 and the pad 115. The dielectric layer 116 and the pad 115 can be on opposite sides of the of the memory layer 111. An end portion of the channel layer 112, an end portion of the memory layer 111 and the end portion 113E2 of the insulating film 113 may contact the pad 115. The pad 115 can be electrically connected to the channel layer 112. The conductive interconnection 165 of the interconnection structure 160 can be electrically connected to the pad 115 and the channel layer 112 of the pillar element 110.

The semiconductor structure 10M may include one or more isolation layers 140. The isolation layer 140 extends along the first direction D1 and penetrates the stack structure ST. An end portion of the isolation layer 140 may extend beyond the stack structure ST. The isolation layer 140 may between two pillar elements 110. The conductive film 120 is on the stack structure ST. The conductive film 120 is on a sidewall of the dielectric layer 116. The conductive film 120 may surround the dielectric layer 116. The conductive film 120 may contact the dielectric layer 116. The insulating material layer 121 is on the conductive film 120. In the present embodiment, a portion of the insulating material layer 121 penetrates the conductive film 120, the conductive film 120 is divided into a first portion 120-1 and a second portion 120-2 by the portion of the insulating material layer 121, and the first portion 120-1 is electrically insulated from second portion 120-2 by the insulating material layer 121. The insulating material layer 121 may surround the dielectric layer 116. The insulating material layer 121 may contact the dielectric layer 116. The conductive structure 122 is in the insulating material layer 123. The conductive structure 122 and the insulating material layer 123 is on the insulating material layer 121. The conductive structure 122 may contact the dielectric layer 116 and the third channel portion 1123 of the channel layer 112. The conductive structure 122 may be electrically connected to a plurality of the pillar elements 110. The dielectric layer 116 may be connected between the memory layer 111 and the conductive structure 122. The via element 124 is in the insulating material layer 125. The via element 124 and the insulating material layer 125 is on the conductive structure 122 and the insulating material layer 123. The insulating material layer 123 is between the insulating material layer 121 and the insulating material layer 125. The conductive element 126 is on the insulating material layer 125. The conductive element 126, the via element 124 and the conductive structure 122 can be electrically connected to each other. The channel layer 112 can be electrically connected between the conductive structure 122 and the conductive interconnection 165 of the interconnection structure 160.

The semiconductor structure 10M may include memory cells. The memory cells are in the stack structure ST. The memory cells can be defined in the memory layer 111 at intersections between the channel layers 112 and the conductive layers 102 of the stack structure ST. The memory cells are electrically connected to the semiconductor elements 195 through the conductive interconnection 165 of the interconnection structure 160 and the conductive interconnection 185 of the interconnection structure 180. The memory cells are electrically connected to the conductive structure 122, the via element 124 and the conductive element 126. The memory cells arranged along the first direction D1 can form a memory string, and a plurality of the memory strings can form a memory array. The conductive structure 122 can be functioned as a common source line for the memory cells (or for controlling the memory cells). The lowermost conductive layer 102 of the stack structure ST can be functioned as a string select line (SSL) for the memory cells (or for controlling the memory cells), and the other conductive layer 102 of the stack structure ST can be functioned as word lines (WL) for the memory cells (or for controlling the memory cells). The conductive film 120 can be functioned as a ground select line (GSL) for the memory cells (or for controlling the memory cells). The conductive film 120, the dielectric layer 116 and the second channel portion 1122 can form a transistor switch. The transistor switch formed by the conductive film 120, the dielectric layer 116 and the second channel portion 1122 can be functioned as a ground select line switch. The semiconductor elements 195 of the semiconductor structure 10P can be used to control operations of the memory cells of the semiconductor structure 10M, such as read operations, program operations, erase operations, etc.

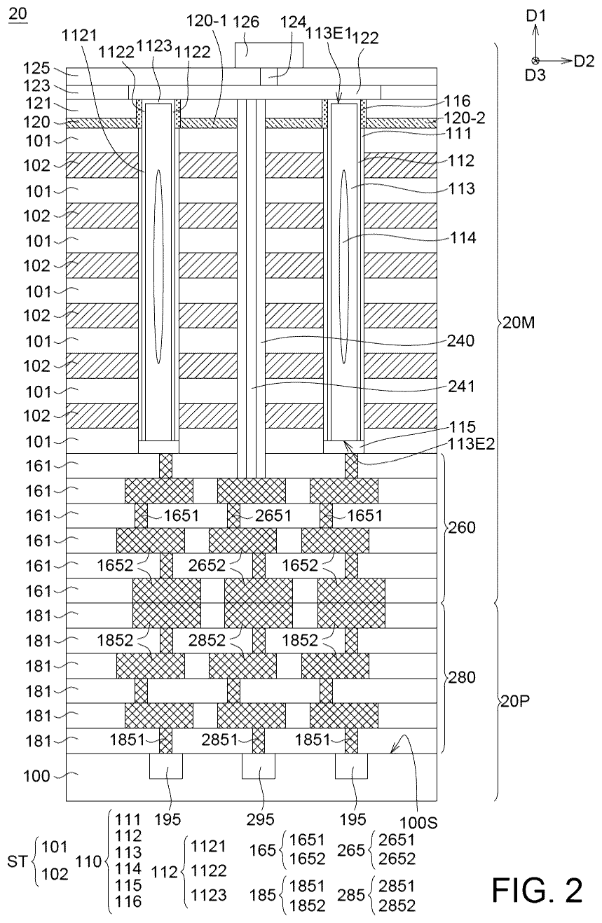

FIG. 2 illustrates a schematic cross-sectional view of a semiconductor device 20 according to some embodiments of the present disclosure. The semiconductor device 20 includes a semiconductor structure 20P and a semiconductor structure 20M. The semiconductor structure 20P is bonded to the semiconductor structure 20M. Among FIG. 1 and FIG. 2, the same reference numerals indicates the same elements with the same properties, and the related descriptions will not be repeated below. The differences between the semiconductor structure 20P and the semiconductor structure 10P shown in FIG. 1 are that, the semiconductor structure 20P further includes a semiconductor element 295 in the substrate 100 and a conductive interconnection 285 electrically connected to the semiconductor element 295.

The semiconductor structure 20P includes a substrate 100, one or more semiconductor elements 195 and one or more semiconductor elements 295 in the substrate 100, and an interconnection structure 280 on the substrate 100. The interconnection structure 280 may include one or more insulating material layers 181, and one or more conductive interconnections 185 and one or more conductive interconnections 285 in the one or more insulating material layers 181. The conductive interconnection 185 may be electrically connected to the semiconductor element 195. In some embodiment, the conductive interconnections 185 and the conductive interconnection(s) 285 are separated from each other by the insulating material layers 181. The conductive interconnection 285 includes one or more via elements 2851 and one or more conductive elements 2852. FIG. 2 shows that the conductive interconnection 285 includes three via elements 2851 and three conductive elements 2852, but the present disclosure is not limited thereto. The conductive interconnection 285 may include more or less via elements 2851 and more or less conductive elements 2852. The via element 2851 is electrically connected to the conductive element 2852. The semiconductor element 195 and the semiconductor element 295 can be peripheral devices. The peripheral device can be used to control the signals transmitted to or from the semiconductor structure 20M. FIG. 2 shows that the semiconductor 295 is in the substrate 100, but the present disclosure is not limited thereto. The semiconductor 295 can be formed on the upper surface 100S of the substrate 100, or partially formed in the substrate 100 (i.e. a portion of the semiconductor element 295 is above the upper surface 100S of the substrate 100 and another portion of the semiconductor element 295 is below the upper surface 100S of the substrate 100), or completely formed in the substrate 100 (i.e. the semiconductor element 295 is completely below the upper surface 100S of the substrate 100). In some embodiments, the semiconductor element 295 is formed in the substrate 100 or on the substrate 100 using a complementary metal-oxide-semiconductor (CMOS) technology.

The differences between the semiconductor structure 20M and the semiconductor structure 10M shown in FIG. 1 are that, the semiconductor structure 20M further includes a conductive interconnection 265 and a conductive strip 241 in the stack structure ST.

The semiconductor structure 20M includes an interconnection structure 260, a stack structure ST, a pillar element 110, an isolation layer 240, a conductive strip 241, a conductive film 120, a conductive structure 122, a via element 124, a conductive element 126, an insulating material layer 121, an insulating material layer 123 and an insulating material layer 125. The interconnection structure 260 is on the interconnection structure 280 and bonded to the interconnection structure 280. The interconnection structure 260 may include one or more insulating material layers 161, and one or more conductive interconnection 165 and one or more conductive interconnection 265 in the one or more insulating material layers 161. In some embodiment, the conductive interconnections 165 and the conductive interconnection(s) 265 are separated from each other by the insulating material layers 161. The conductive interconnection 265 includes one or more via elements 2651 and one or more conductive elements 2652. FIG. 1 shows that the conductive interconnection 265 includes three via elements 2651 and three conductive elements 2652, but the present disclosure is not limited thereto. The conductive interconnection 265 may include more or less via elements 2651 and more or less conductive elements 2652. The via element 2651 is electrically connected to the conductive element 2652. The insulating material layers 161 of the interconnection structure 260 can be bonded to the insulating material layers 181 of the interconnection structure 280. The conductive elements 1652 of the interconnection structure 260 can be bonded to the conductive elements 1852 of the interconnection structure 280. The conductive elements 2652 of the interconnection structure 260 can be bonded to the conductive elements 2852 of the interconnection structure 280. The conductive interconnection 265 can be electrically connected to the conductive interconnection 285. The conductive strip 241 extends along the first direction D1 and penetrates the stack structure ST. The isolation layer 240 is on the sidewall of the conductive strip 241. The isolation layer 240 may cover the sidewall of the conductive strip 241. The conductive strip 241 can be separated from the stack structure ST by the isolation layer 240. The conductive strip 241 can be electrically insulated from the conductive layers 102 of the stack structure ST. The conductive strip 241 can be electrically connected between the conductive structure 122 and the conductive interconnection 265 of the interconnection structure 260. In the present embodiment, the conductive film 120 is divided into a first portion 120-1 and a second portion 120-2 by the isolation layer 240 and the conductive strip 241, and the first portion 120-1 is electrically insulated from second portion 120-2 by the isolation layer 240. The conductive strip 241 can be functioned as a source line (SL) for the memory cells (or for controlling the memory cells) of the semiconductor structure 20M. The semiconductor elements 195 and the semiconductor element(s) 295 of the semiconductor structure 20P can be used to control operations of the memory cells of the semiconductor structure 20M, such as read operations, program operations, erase operations, etc.

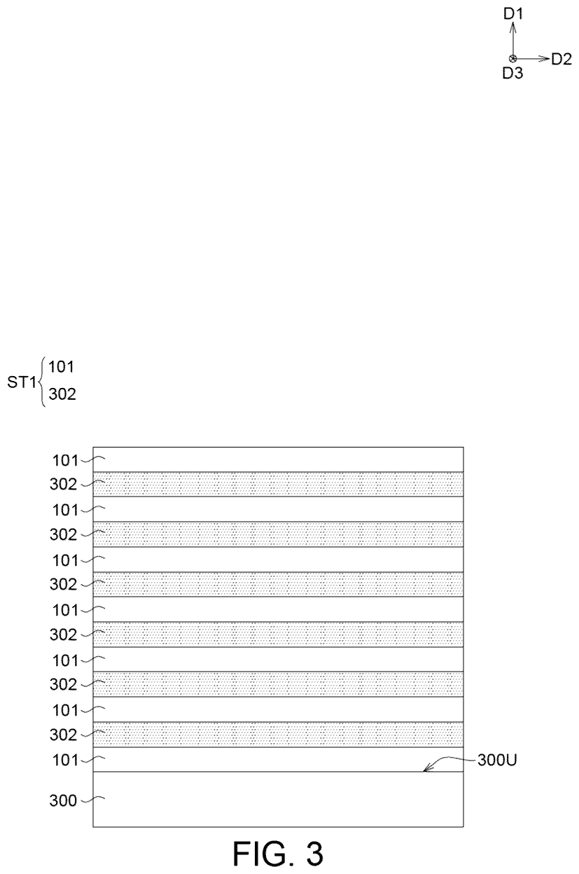

FIG. 3 to FIG. 22 illustrate schematic cross-sectional views of various stages of a method for manufacturing a semiconductor device according to some embodiments of the present disclosure.

FIG. 3 illustrates a schematic view of a structure at a stage of the method for manufacturing the semiconductor device. A substrate 300 is provided. The substrate 300 can be a semiconductor substrate. The substrate 300 may include a semiconductor material, such as doped or undoped monocrystalline silicon, doped or undoped polycrystalline silicon, germanium, etc. In some embodiment, the substrate 300 can be a carrier wafer, such as a lower cost wafer or a reclaim wafer. An insulating stack structure ST1 is formed on the substrate 300. The insulating stack structure ST1 includes insulating layers 101 and insulating layers 302 stacked alternately along the first direction D1 on the upper surface 300U of the substrate 300. The insulating layers 302 are separated from each other by the insulating layers 101. The insulating layers 101 and the insulating layers 302 may extend along a second direction D2 and/or a third direction D3. The first direction D1, the second direction D2 and the third direction D3 are perpendicular to each other. In the present embodiment, the uppermost layer and the lowermost layer of the insulating stack structure ST1 are both insulating layers 101. The uppermost insulating layer 101 of the insulating stack structure ST1 can be used as a hard mask. The lowermost insulating layer 101 of the insulating stack structure ST1 can contact the substrate 300. FIG. 3 shows seven insulating layers 101 and six insulating layers 302, but the present disclosure is not limited thereto. The stack structure ST may include more or less insulating layers 101 and more or less insulating layers 302.

The insulating layer 101 may have a thickness in the first direction D1 ranging from 50 Å (Angstroms) to 600 Å, such as 150 Å˜300 Å. The insulating layer 302 may have a thickness in the first direction D1 ranging from 50 Å to 600 Å, such as 150 Å˜350 Å. The insulating layer 101 and the insulating layer 302 may include different materials. The insulating layer 101 may include an insulating material including oxide. In some embodiments, the insulating layer 101 includes silicon oxide. The insulating layer 302 may include an insulating material including nitride. In some embodiments, the insulating layer 302 includes silicon nitride. In some embodiments, the insulating layer 101 is a silicon oxide layer and the insulating layer 302 is a silicon nitride layer. In some embodiments, the insulating stack structure ST1 is formed by forming the insulating layers 101 and the insulating layers 302 alternately on the upper surface 300U of the substrate 300 through a deposition process.

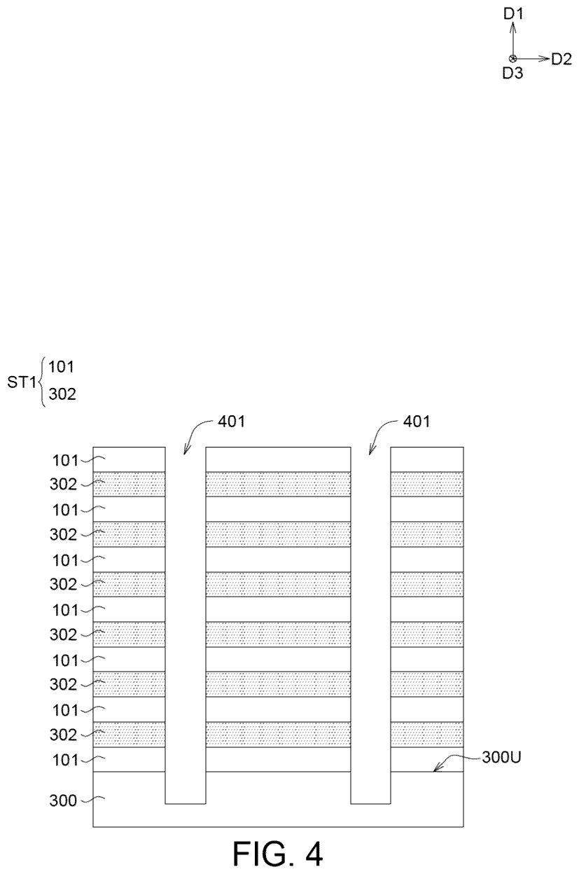

FIG. 4 illustrates a schematic view of a structure at a stage of the method for manufacturing the semiconductor device. Openings 401 are formed in the insulating stack structure ST1. The openings 401 are separated from each other. The opening 401 extends along the first direction D1, penetrates the insulating layers 101 and the insulating layers 302 of the insulating stack structure ST1, and stop at the substrate 300. A bottom of the opening 401 can be lower than the upper surface 300U of the substrate in the first direction D1. The sidewalls of the insulating stack structure ST1 and the substrate 300 are exposed by the openings 401. The opening 401 may have any shape such as a cylindrical, elliptical cylindrical or square columnar shape. In some embodiments, a portion of the insulating layers 101, a portion of the insulating layers 302, and a portion of the substrate are removed through an etching process to form the openings 401.

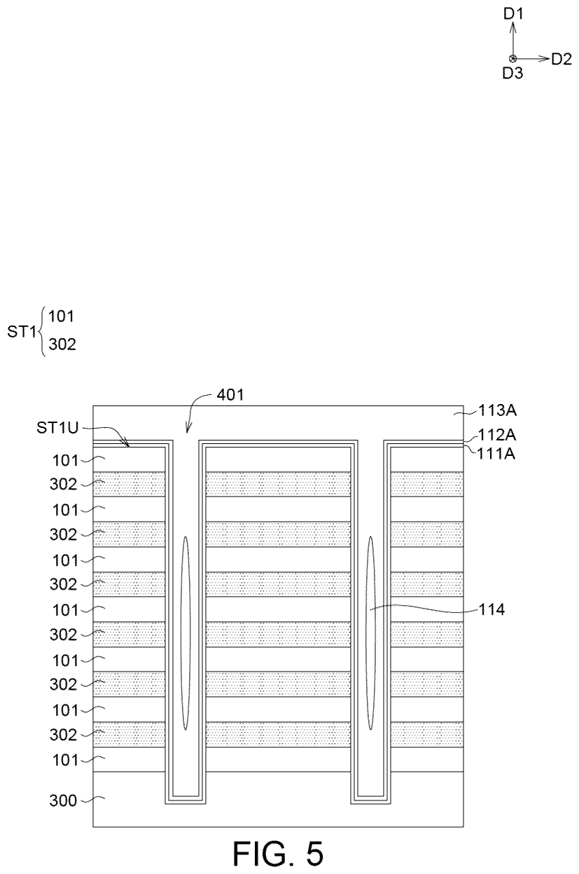

FIG. 5 illustrates a schematic view of a structure at a stage of the method for manufacturing the semiconductor device. A memory layer 111A, a channel layer 112A, an insulating film 113A and an air gap 114 are formed. The memory layer 111A, the channel layer 112A and the insulating film 113 can fill the openings 401 can be formed on an upper surface ST1U of the insulating stack structure ST1. A portion of the memory layer 111A can be between the channel layer 112A and the insulating stack structure ST1. A portion of the memory layer 111A can be between the channel layer 112A and the substrate 300. The channel layer 112A can be between the memory layer 111A and the insulating film 113A. The air gap 114 can be in the insulating film 113A. The memory layer 111A may include a multilayer structure known from memory technologies, such as ONO (oxide-nitride-oxide) structure, ONONO (oxide-nitride-oxide-nitride-oxide) structure, ONONONO (oxide-nitride-oxide-nitride-oxide-nitride-oxide) structure, SONOS (silicon-oxide-nitride-oxide-silicon) structure, BE-SONOS (bandgap engineered silicon-oxide-nitride-oxide-silicon) structure, TANOS (tantalum nitride, aluminum oxide, silicon nitride, silicon oxide, silicon) structure, MA BE-SONOS (metal-high-k bandgap-engineered silicon-oxide-nitride-oxide-silicon) structure, MONOS (metal-oxide-nitride-oxide-silicon) structure, or combinations of those layers. The channel layer 112A may include a semiconductor material such as doped or undoped monocrystalline silicon, polycrystalline silicon, germanium, etc. In some embodiments, the channel layer 112A includes undoped polycrystalline silicon. The insulating film 113A may include an insulating material including oxide. In some embodiment, the insulating film 113A includes silicon oxide.

In some embodiment, the memory layer 111A is formed on the upper surface ST1U of the insulating stack structure ST1, the sidewalls of the insulating layers 101 exposed by the openings 401, the sidewalls of the insulating layers 302 exposed by the openings 401, and the substrate 300 exposed by the openings 401 through a deposition process; the channel layer 112A are formed on the memory layer 111A through a deposition process, a portion of the channel layer 112A is formed in the openings 401, and a portion of the channel layer 112A is formed on the insulating stack structure ST1; the insulating film 113A are formed in the remaining spaces of the openings 401 through a deposition process, and a portion of the insulating film 113A is formed on the insulating stack structure ST1. In the process of forming the insulating film 113A, the air gaps 114 may be formed within the insulating film 113A. In some embodiments, there may be no air gap 114 within the insulating film 113A.

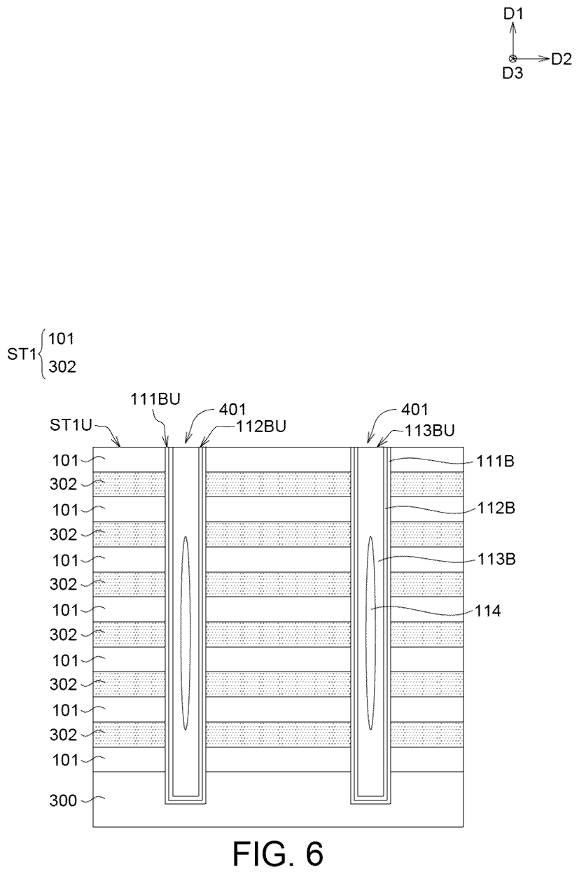

FIG. 6 illustrates a schematic view of a structure at a stage of the method for manufacturing the semiconductor device. A memory layer 111B, a channel layer 112B and an insulating film 113B are formed in the insulating stack structure ST1. The air gap 114 is within the insulating film 113B. The memory layer 111B, the channel layer 112B and the insulating film 113B extends along the first direction D1 and penetrates the insulating stack structure ST1. An upper surface 113BU of the insulating film 113B, a terminal surface 112BU of the channel layer 112B, a terminal surface 111BU of the memory layer 111B and the upper surface ST1U of the insulating stack structure ST1 can be coplanar. In some embodiments, a portion of the memory layer 111A above the insulating stack structure ST1, a portion of the channel layer 112A above the insulating stack structure ST1, and a portion of the insulating film 113A above the insulating stack structure ST1 are removed through a polishing process, and a portion of the memory layer 111A in the openings 401, a portion of the channel layer 112A in the openings 401, and a portion of the insulating film 113A in the openings 401 are retained to form the structure shown in FIG. 6. The portion of the memory layer 111A in the opening 401 is the memory layer 111B. The portion of the channel layer 112A in the opening 401 is the channel layer 112B. The portion of the insulating film 113A in the opening 401 is the insulating film 113B.

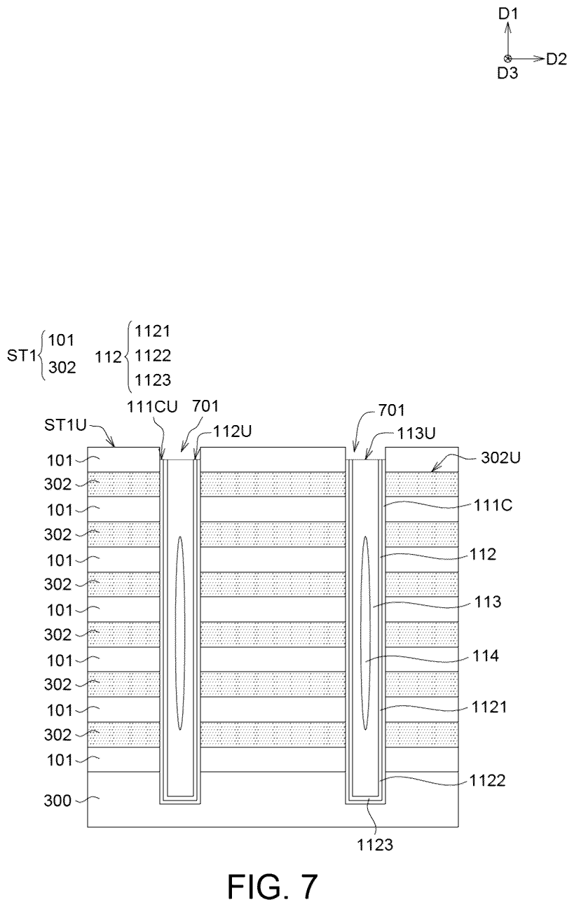

FIG. 7 illustrates a schematic view of a structure at a stage of the method for manufacturing the semiconductor device. A memory layer 111C, a channel layer 112 and an insulating film 113 are formed in the insulating stack structure ST1. The air gap 114 is within the insulating film 113. The memory layer 111C, the channel layer 112 and the insulating film 113 extends along the first direction D1 and penetrates the insulating stack structure ST1. The memory layer 111C may surround the channel layer 112. The upper surface 113U of the insulating film 113, a terminal surface 112U of the channel layer 112, and a terminal surface 111U of the memory layer 111CU can be coplanar. The upper surface 113U of the insulating film 113, the terminal surface 112U of the channel layer 112, and the terminal surface 111U of the memory layer 111CU can be higher than an upper surface 302U of the uppermost insulating layer 302 among the insulating layers 302 in the first direction D1. The upper surface 113U of the insulating film 113, the terminal surface 112U of the channel layer 112, and the terminal surface 111U of the memory layer 111CU can be lower than the upper surface ST1U of the insulating stack structure ST1 in the first direction D1. The channel layer 112 includes a first channel portion 1121, a second channel portion 1122 and a third channel portion 1123. The third channel portion 1123 is in the substrate 300. At least a portion of the second channel portion 1122 is in the substrate 300. In some embodiment, a portion of the memory layer 111B, a portion of the channel layer 112B and a portion of the insulating film 113B are removed through an etching back process to form recesses 701. The retained portion of the memory layer 111B is the memory layer 111C. The retained portion of the channel layer 112B is the channel layer 112. The retained portion of insulating film 113B is the insulating film 113. In some embodiments, the etching back process used at this stage can be a wet etching process using hydrofluoric acid (HF), or can be a dry etching process using hydrofluoric acid/ammonia (HF/NH₃) or nitrogen trifluoride/ammonia (NF₃/NH₃).

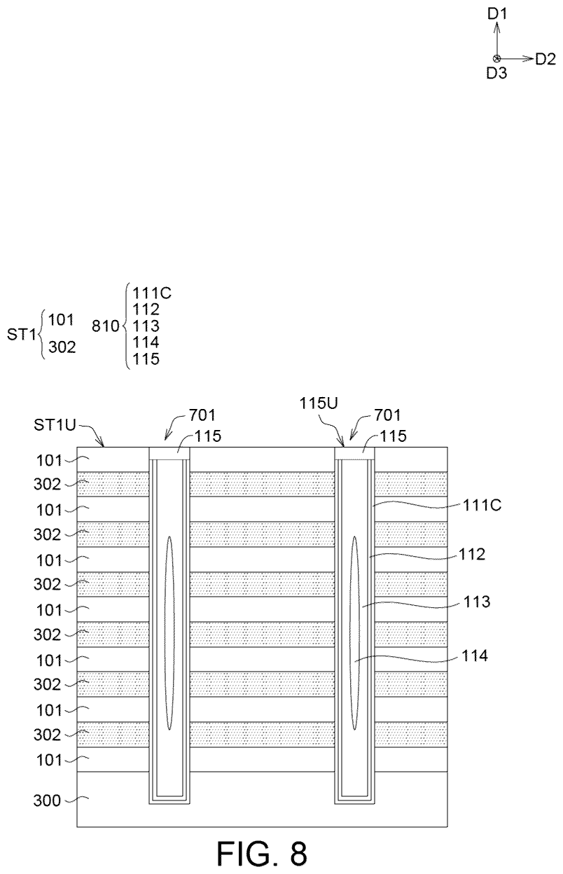

FIG. 8 illustrates a schematic view of a structure at a stage of the method for manufacturing the semiconductor device. A pad 115 is formed. An upper surface 115U of the pad 115 can be coplanar with the upper surface ST1U of the insulating stack structure ST1. In some embodiment, a pad material can be formed in the recesses 701 and on the upper surface ST1U of the insulating stack structure ST1 through a deposition process; then, a portion of the pad material above the upper surface ST1U of the insulating stack structure ST1 is removed through a polishing process, and a portion of the pad material in the recesses 701 is retained to form pillar structures 810. The pillar structure 810 includes the memory layer 111C, the channel layer 112, the insulating film 113, the air gap 114 and the pad 115. The portion of the pad material in the recesses 701 is the pad 115. The pad material and the pad 115 may include semiconductor materials, such as doped or undoped monocrystalline silicon, polycrystalline silicon, germanium, etc. In some embodiments, the pad material and the pad 115 include N-type doped polycrystalline silicon. In some embodiments, the pad material and the pad 115 include N-type highly doped polycrystalline silicon (N+ polycrystalline silicon).

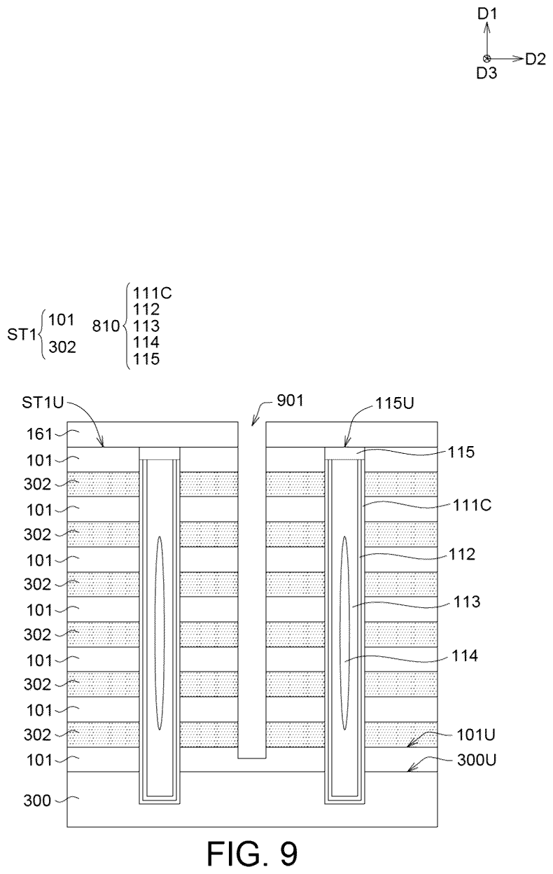

FIG. 9 illustrates a schematic view of a structure at a stage of the method for manufacturing the semiconductor device. An insulating material layer 161 is formed on the insulating stack structure ST1. An opening 901 is formed in the insulating stack structure ST1. The opening 901 extends along the first direction D1, penetrates the insulating stack structure ST1 and the insulating material layer 161, and stop at the insulating layer 101 of the insulating stack structure ST1. In the present embodiment, the opening 901 stops at the lowermost insulating layer 101 among the insulating layers 101. A bottom of the opening 901 can be higher than the upper surface 300U of the substrate 300 in the first direction D1. The bottom of the opening 901 can be lower than an upper surface 101U of the lowermost insulating layer 101 among the insulating layers 101 in the first direction D1. The opening 901 may be between the pillar structures 810. A sidewall of the insulating material layer 161 and a sidewall of the insulating stack structure ST1 are exposed by the opening 901. The insulating material layer 161 may include an insulating material including oxide. In some embodiments, the insulating material layer 161 includes silicon oxide. In some embodiments, the insulating material layer 161 is formed on the upper surface ST1U of the insulating stack structure ST1; a portion of the insulating material layer 161, a portion of the insulating layers 101 and a portion of the insulating layers 302 are removed through an etching process to form the opening 901.

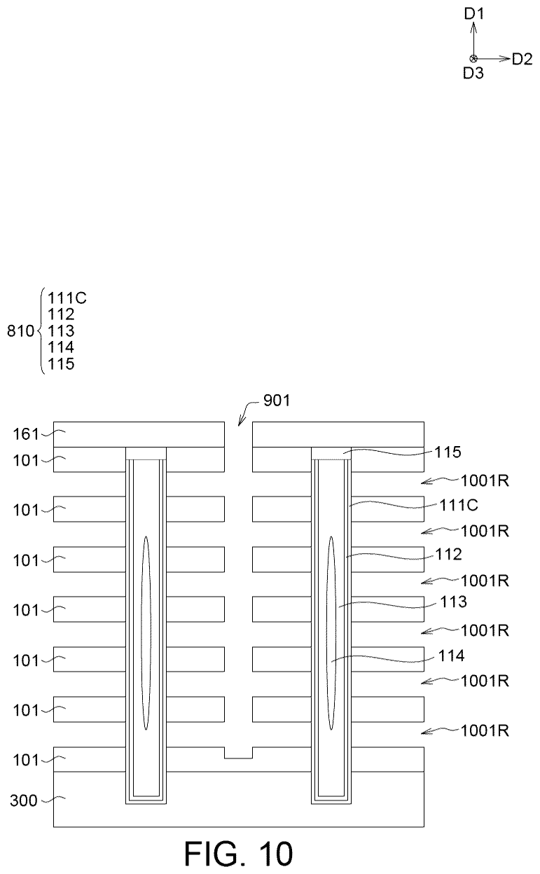

FIG. 10 illustrates a schematic view of a structure at a stage of the method for manufacturing the semiconductor device. Spaces 1001R are formed. The spaces 1001R are between the insulating layers 101. The spaces 1001R can be connected to the opening 901. The upper surfaces of the insulating layers 101, the lower surfaces of the insulating layers 101, and a portion of an outer sidewalls of the memory layers 111C of the pillar structures 810 are exposed by the spaces 1001R. In some embodiments, the insulating layers 302 between the insulating layers 101 are removed through a selectively etching process to form the spaces 1001R, and the insulating layers 101, the insulating material layer 161, the pillar structures 810 and the substrate 300 are retained. The selectively etching process can be performed through the opening 901. In some embodiments, phosphoric acid (H₃PO₄) can be used to remove the insulating layers 302. During this stage, the pillar structures 810 may serve as structural support.

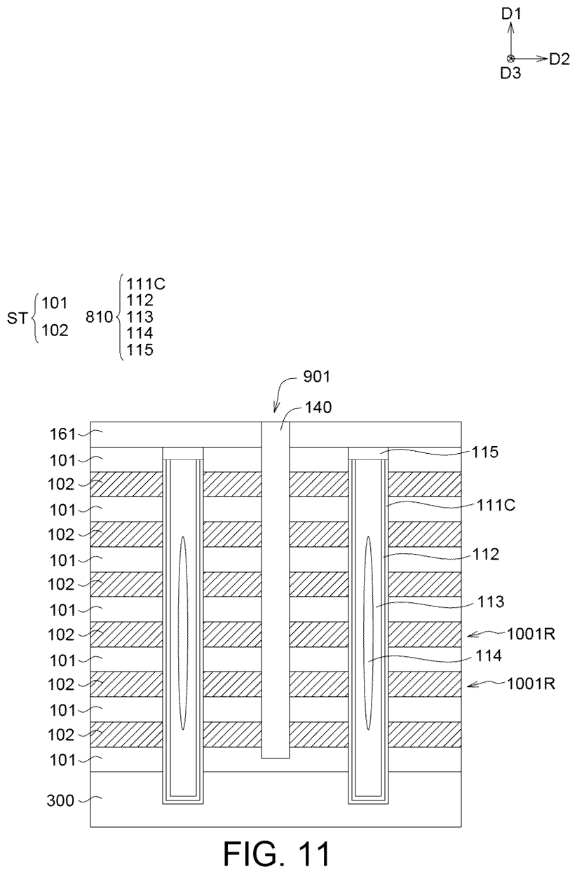

FIG. 11 illustrates a schematic view of a structure at a stage of the method for manufacturing the semiconductor device. A stack structure ST including conductive layers 102 and the insulating layers 101, and an isolation layer 140 in the stack structure ST are formed. The conductive layers 102 are between the insulating layers 101. The conductive layers 102 may extend along the second direction D2 and/or the third direction D3. The isolation layer 140 extends along the first direction D1 and penetrates the stack structure ST and the insulating material layer 161. The isolation layer 140 may be between the pillar structures 810. The isolation layer 140 may include an insulating material including oxide. In some embodiment, the isolation layer 140 includes silicon oxide. The conductive layer 102 may include a conductive material, and the conductive material includes, but is not limited to, doped or undoped polycrystalline silicon, metal and combinations thereof. The conductive layer 102 may include a combination of metal and a dielectric material with a high dielectric constant (high-k dielectric material). The conductive layer 102 may include a multilayer structure, such as a multilayer structure formed by metal layers, a multilayer structure formed by one or more metal layers and one or more high-k dielectric layers, etc. The high-k dielectric material refers to a material with a dielectric constant greater than 3.9. The high-k dielectric material includes, but is not limited to, Si₃N₄, AlOₓ, La₂O₃, Ta₂O₅, Y₂O₃, TiO₂, HfOₓ, ZrOₓ, etc.; x is greater than zero. In some embodiment, the conductive layer 102 includes a AlOₓ/TiN/W multilayer structure. In some embodiment, the spaces 1001R is filled with the conductive layers 102 through a deposition process to form the stack structure ST; the opening 901 is filled with the isolation layer 140 through a deposition process.

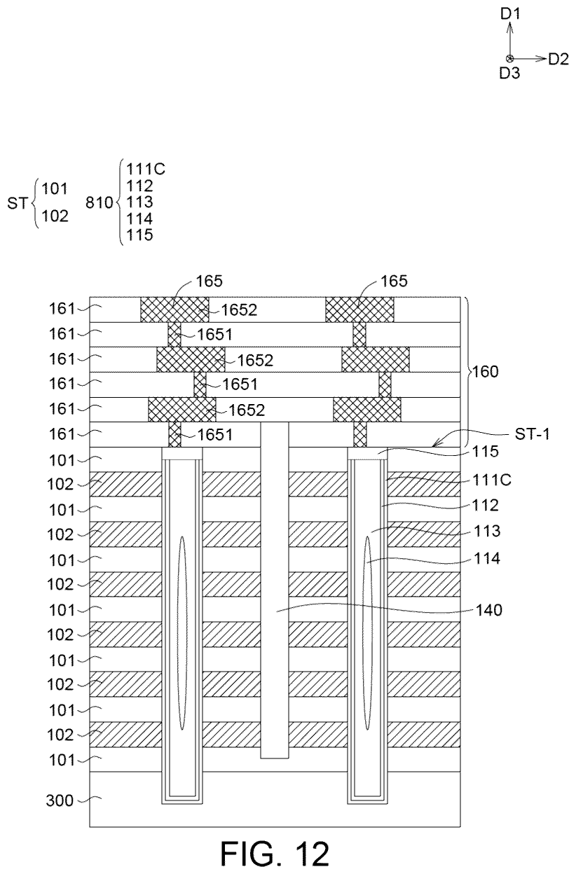

FIG. 12 illustrates a schematic view of a structure at a stage of the method for manufacturing the semiconductor device. An interconnection structure 160 is formed on an surface ST-1 of the stack structure ST. The interconnection structure 160 includes insulating material layers 161 and conductive interconnections 165 in the insulating material layers 161. In the present embodiment, two conductive interconnections 165 correspond to different pillar structures 810. Two conductive interconnections 165 are electrically connected to different pillar structures 810. The conductive interconnection 165 includes via elements 1651 and conductive elements 1652. The via elements 1651 and the conductive elements 1652 may include the same or different materials. The via elements 1651 and the conductive elements 1652 may include conductive materials, and the conductive materials include, but is not limited to, metal. For example, the via elements 1651 and the conductive elements 1652 may include TiN, TaN, Ti, Ta, Cu, Al, Ag, W, Ir, Ru, Pt and combinations thereof. In some embodiments, the via elements 1651 and the conductive elements 1652 include copper (Cu). In some embodiments, the insulating material layer 161 is formed through a deposition process, one or more grooves can be formed in the insulating material layer 161 through a patterning process, the position of the groove(s) is the position where the via element(s) 1651 and/or the conductive element(s) 1652 will be formed, and then the grooves are filled with the material of the via element 1651 and/or the material of the conductive element 1652 to form the via element(s) 1651 and/or the conductive element(s) 1652 in the insulating material layer 161; the above steps can be repeated until the configuration of the conductive interconnection 165 meets the requirements. In some embodiments, the interconnection structure 160 can be understood as a memory array interconnection structure. The conductive elements 1652 in the insulating material layer 161 that are farthest from the pillar structures 810 in the first direction D1 can be understood as bonding layers, and the bonding layers can be used to bond to other structures. In some embodiments, the insulating material layers 161 can be understood as inter-metal dielectric (IMD) layers.

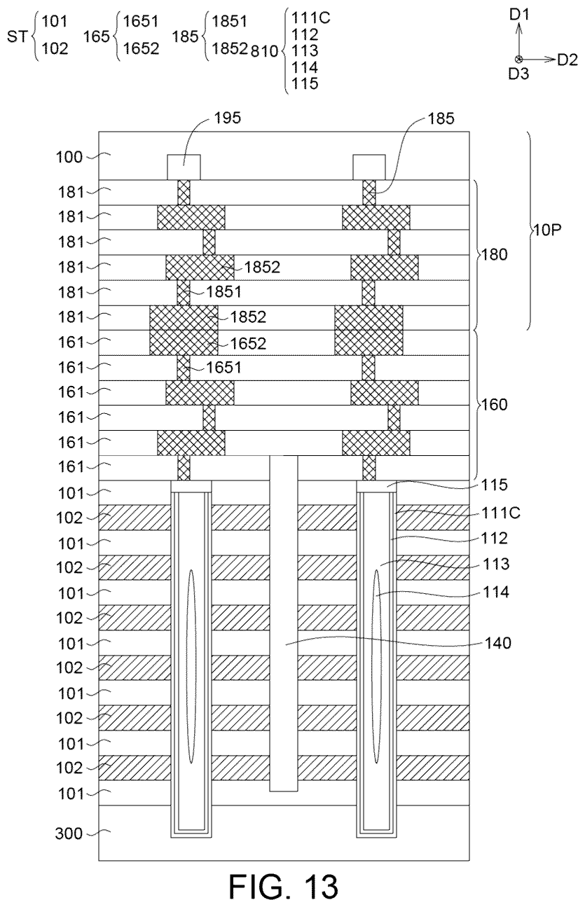

FIG. 13 illustrates a schematic view of a structure at a stage of the method for manufacturing the semiconductor device. A semiconductor structure 10P is provided. The semiconductor structure 10P is bonded to the interconnection structure 160. The semiconductor structure 10P includes a substrate 100, semiconductor elements 195 in the substrate 100, and an interconnection structure 180 on the substrate 100 and the semiconductor elements 195. The interconnection structure 180 may include insulating material layers 181 and conductive interconnections 185 in the insulating material layers 181. The conductive interconnections 185 are electrically connected to different semiconductor elements 195. The conductive interconnections 185 includes via elements 1851 and conductive elements 1852. The via elements 1851 and the conductive elements 1852 may include the same or different materials. The via elements 1851 and the conductive elements 1852 may include conductive materials, and the conductive materials include, but are not limited to, metal. For example, the via elements 1851 and the conductive elements 1852 may include TiN, TaN, Ti, Ta, Cu, Al, Ag, W, Ir, Ru, Pt and combinations thereof. In some embodiments, the via elements 1851 and the conductive elements 1852 include Cu. The conductive elements 1852 in the insulating material layer 181 that are farthest from the substrate 100 in the first direction D1 can be understood as bonding layers, and the bonding layers can be used to bond to other structures (e.g. the interconnection structure 160). The method for manufacturing the interconnection structure 180 may be similar to the method for manufacturing the interconnection structure 160. In some embodiments, a solid state bonding technology such as a diffusion bonding technology can be used to bond the bonding layers (the conductive elements 1852) of the interconnection structure 180 of the semiconductor structure 10P to the bonding layers (the conductive elements 1652) of the interconnection structure 160. The bonding of the semiconductor structure 10P and the interconnection structure 160 may be a Cu—Cu hybrid bonding.

After the semiconductor structure 10P is bonded to the interconnection structure 160, the conductive interconnections 185 of the semiconductor structure 10P can be electrically connected to different conductive interconnections 165 of the interconnection structure 160, and thus the semiconductor element 195 can be electrically connected to the pillar structure 810 through a corresponding conductive interconnection 185, and a corresponding conductive interconnection 165.

In some embodiments, the interconnection structure 180 can be a middle-end-of-line (MEOL) interconnection structure or a back-end-of-line (BEOL) interconnection structure.

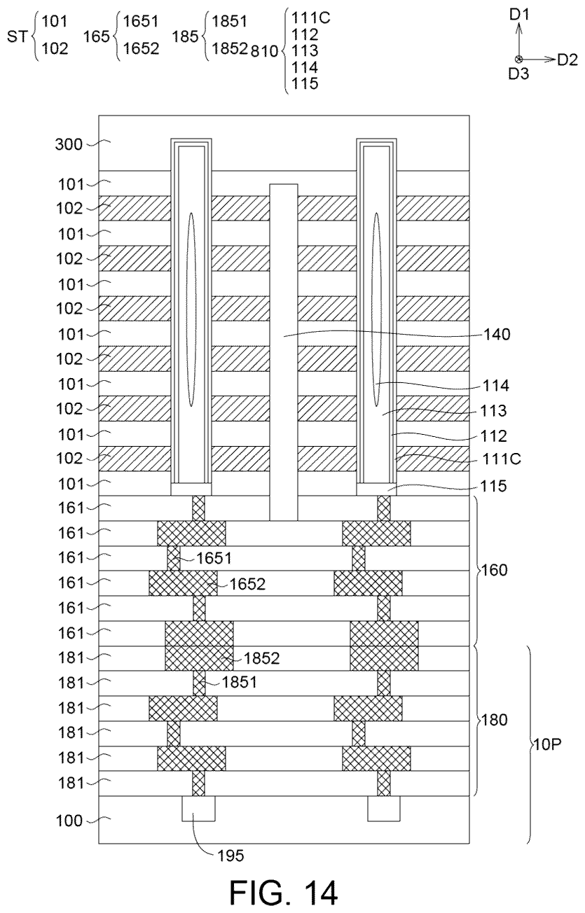

FIG. 14 illustrates a schematic view of a structure at a stage of the method for manufacturing the semiconductor device. The structure shown in FIG. 13 is rotated. After the rotation, the substrate 300 is above the substrate 100. In some embodiments, the manufacturing method may omit the rotation step.

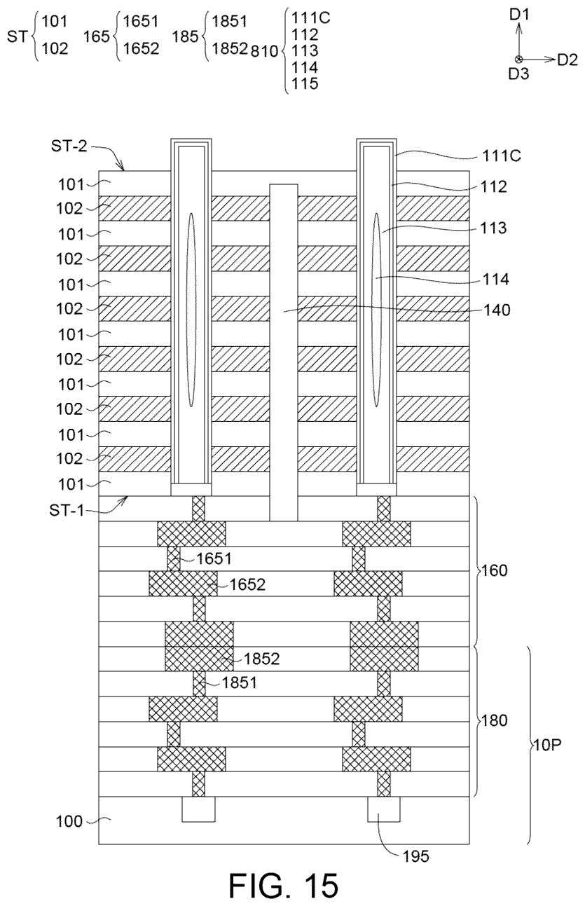

FIG. 15 illustrates a schematic view of a structure at a stage of the method for manufacturing the semiconductor device. A portion of the pillar structures 810 is exposed. In some embodiments, the substrate 300 is removed through an etching process to expose the portion of the pillar structures 810 that was previously in the substrate 300 and expose a surface ST-2 of the stack structure ST. The surface ST-2 of the stack structure ST is opposite to the surface ST-1 of the stack structure ST.

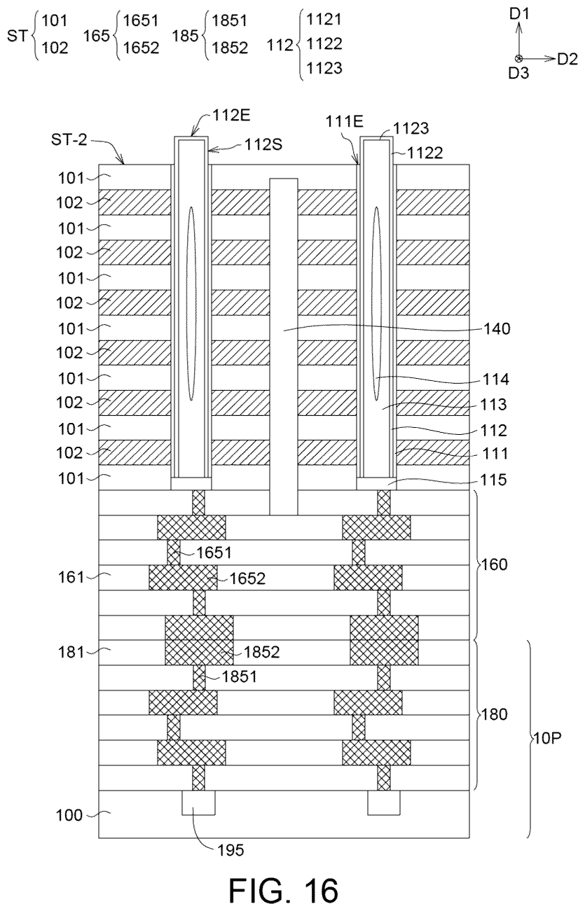

FIG. 16 illustrates a schematic view of a structure at a stage of the method for manufacturing the semiconductor device. A memory layer 111 is formed. A portion of the channel layer 112 is exposed. In some embodiments, a portion of the memory layer 111C is removed through an etching process to expose the second channel portion 1122 and the third channel portion 1123 of the channel 112. A portion of the memory layer 111C in the stack structure ST is retained during the etching process. The portion of the memory layer 111C in the stack structure ST is the memory layer 111. Removing a portion of the memory layer 111C exposes a portion of a sidewall 112S of the channel layer 112 and a terminal surface 112E of the channel layer 112. A terminal surface 111E of the memory layer 111 is lower than the terminal surface 112E of the channel layer 112 in the first direction D1.

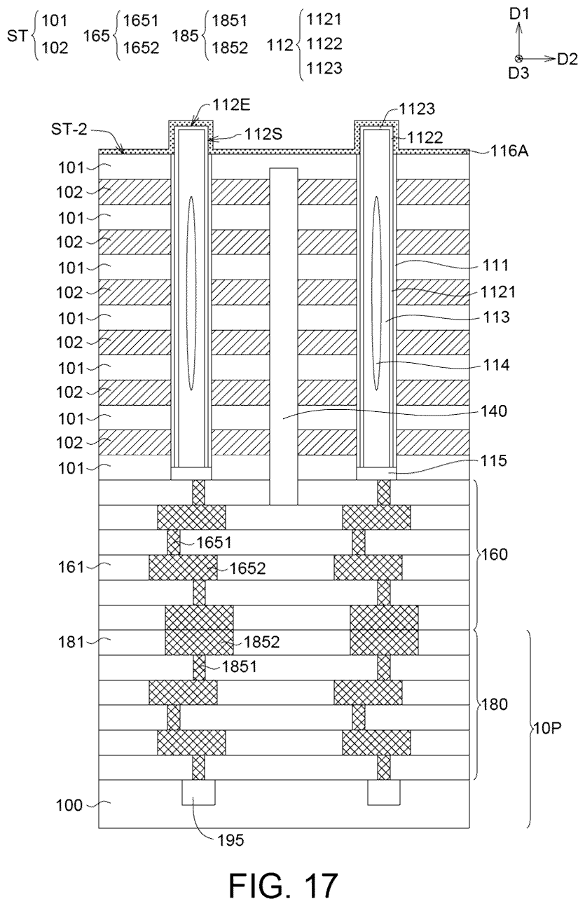

FIG. 17 illustrates a schematic view of a structure at a stage of the method for manufacturing the semiconductor device. A dielectric layer 116A is formed on the stack structure ST and the channel layer 112. In some embodiments, the dielectric layer 116A is formed on the surface ST-2 of the stack structure ST, the exposed sidewall 112S of the channel layer 112 and the exposed terminal surface 112E of the channel layer 112 through a deposition process.

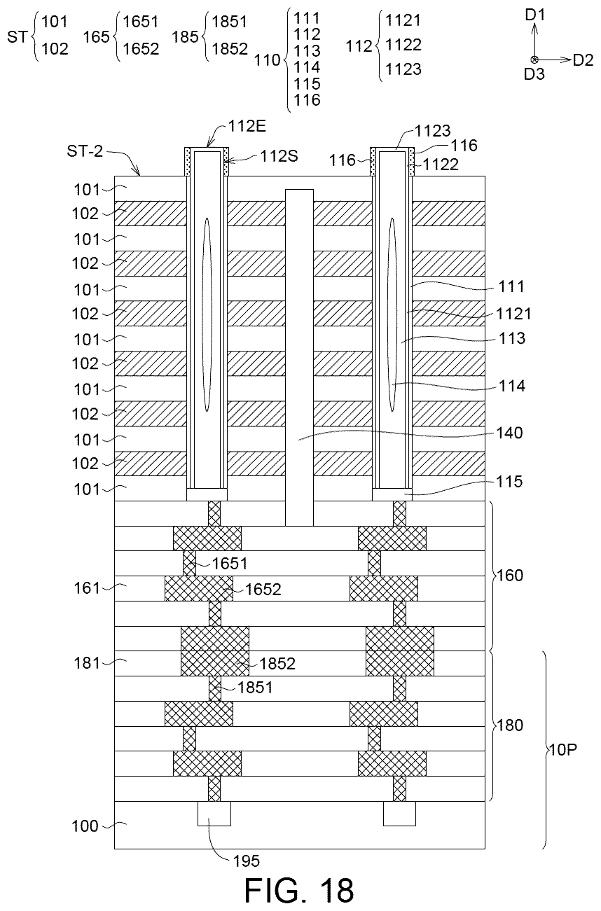

FIG. 18 illustrates a schematic view of a structure at a stage of the method for manufacturing the semiconductor device. A dielectric layer 116 is formed. The dielectric layer 116 is formed on the sidewall 112S of the channel layer 112. A width of the dielectric layer 116 in the second direction D2 may be smaller than a width of the memory layer 111 in the second direction D2. The dielectric layer 116 and the memory layer 111 includes different materials. The dielectric layer 116 may include a dielectric material, and the dielectric material includes, but is not limited to, SiOₓ, SiON, SiN, AlOₓ, HfOₓ, ZrOₓ, HfZrₓO_{y}, and combinations thereof; x and y are greater than zero. In some embodiments, the dielectric layer 116 includes thin silicon nitride having a thickness which can range from 5 Å to 30 Å. For example, the thickness of the thin silicon nitride is 20 Å. In some embodiments, the dielectric layer 116 includes a multilayer structure, such as an ONO (oxide-nitride-oxide) structure formed of thin silicon nitride. In some embodiments, the dielectric layer 116 includes doped HfZrₓO_{y}, and the operation of the dielectric layer 116 is not based on the ferroelectric effect. In some embodiments, the dielectric layer 116 includes a high-k dielectric material, which can improve the electrical performance of the semiconductor device. In some embodiments, a portion of the dielectric layer 116A on the surface ST-2 of the stack structure ST and a portion of the dielectric layer 116A on the terminal surface 112E of the channel layer 112 are removed through an etching process to expose the surface ST-2 of the stack structure ST and the terminal surface 112E of the channel layer 112. A portion of the dielectric layer 116A on the sidewall 112S of the channel layer 112 is retained during the etching process. The retained portion of the dielectric layer 116A is the dielectric layer 116. Therefore, a pillar element 110 including the memory layer 111, the channel layer 112, the insulating film 113, the air gap 114, the pad 115 and the dielectric layer 116 is formed.

In other embodiments, the dielectric layer 116 can be formed through oxidation process. For example, an oxidation process is performed to the channel layer 112 shown in FIG. 16 to convert the exposed portion (e.g. the second channel portion 1122 and the third channel portion 1123) of the channel layer 112 to an oxidized portion; then, an etching process is performed to remove a portion of the oxidized portion on the terminal surface 112E of the channel layer 112 and a portion of the oxidized portion on the sidewall 112S of the channel layer 112 is retained; the retained portion of the oxidized portion is the dielectric layer 116. The aforementioned oxidation process will not cause all the exposed portion of the channel layer 112 to be oxidized, but will only cause the portion of the channel layer 112 near the outer surface of the channel layer 112 to be oxidized and converted to the oxidized portion; the portion of the channel layer 112 close to the insulating film 113 is not oxidized. Therefore, after the etching process, the insulating film 113 is still covered by the channel layer 112 without being exposed.

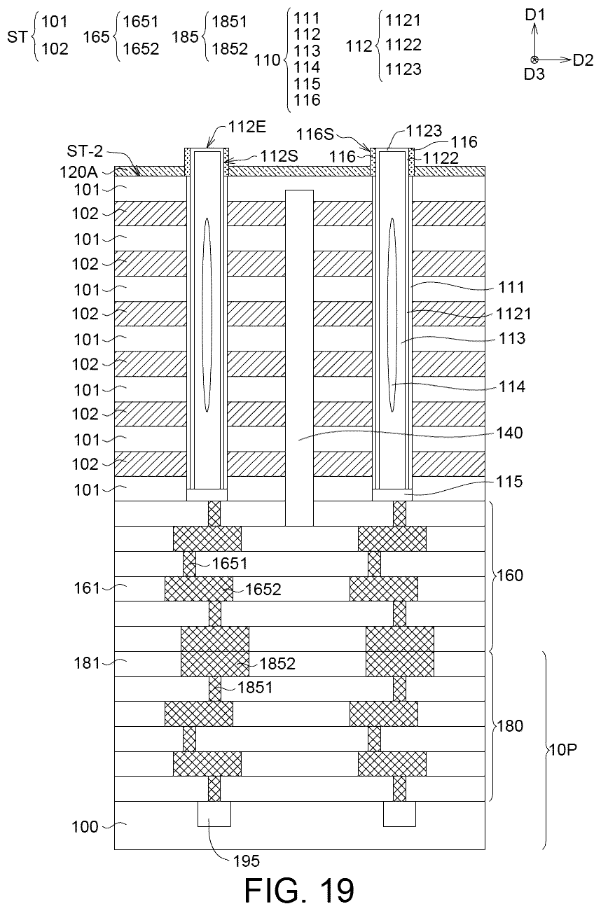

FIG. 19 illustrates a schematic view of a structure at a stage of the method for manufacturing the semiconductor device. A conductive film 120A is formed. In some embodiments, a conductive material is formed on the surface ST-2 of the stack structure ST, the outer sidewall 116S of the dielectric layer 116 and the terminal surface 112E of the channel layer 112 through a deposition process; a portion of the conductive material on the outer sidewall 116S of the dielectric layer 116 and a portion of the conductive material on the terminal surface 112E of the channel layer 112 can be removed through an etching back process, and a portion of the conductive material on the surface ST-2 of the stack structure ST is retained. The retained portion of the conductive material on the surface ST-2 of the stack structure ST is the conductive film 120A.

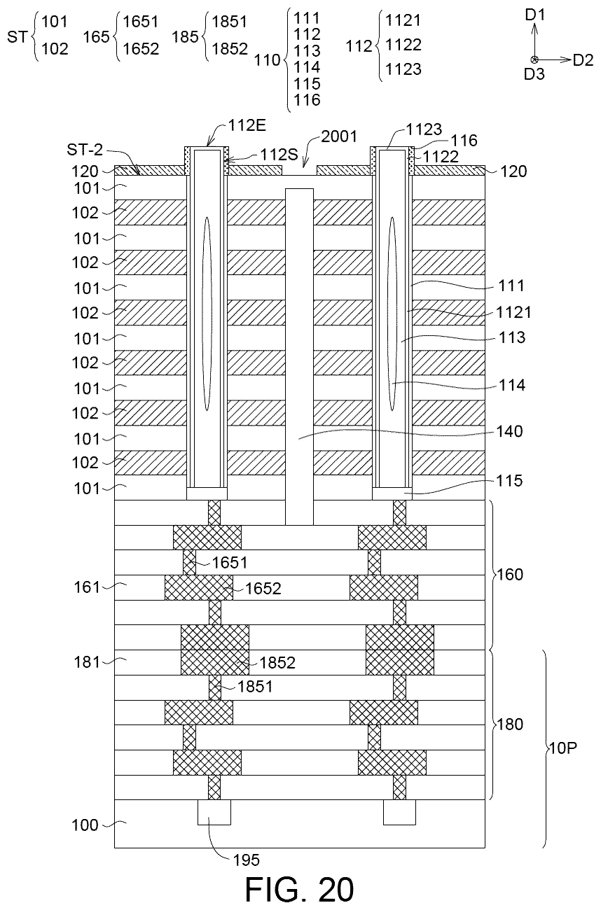

FIG. 20 illustrates a schematic view of a structure at a stage of the method for manufacturing the semiconductor device. A conductive film 120 and an opening 2001 in the conductive film 120 are formed. The opening 2001 extends along the first direction D1, penetrates the conductive film 120, and stop at the surface ST-2 of the stack structure ST. A portion of the surface ST-2 of the stack structure ST is exposed by the opening 2001. The sidewalls of the conductive film 120 are exposed by the opening 2001. The position of the opening 2001 can correspond to the position of the isolation layer 140. In the first direction D1, the opening 2001 may at least partially overlap the isolation layer 140. In some embodiments, a portion of the conductive film 120A is removed through an etching process to form the opening 2001. The retained portion of the conductive film 120A is the conductive film 120.

The conductive film 120 and the conductive layer 102 may include the same or different materials. The conductive film 120 may include a conductive material, and the conductive material includes, but is not limited to, doped or undoped polycrystalline silicon, metal, silicide, and the combinations thereof. The conductive film 120 may include a multilayer structure, such as a multilayer structure formed by metal layers, a multilayer structure formed by metal and polycrystalline silicon, a multilayer structure formed by polycrystalline silicon and silicide, etc. In some embodiments, the conductive film 120 includes TiN/W, TaN/W, TiN, TaN, TaAlN, TiAlN, N-type doped polycrystalline silicon, P-type doped polycrystalline silicon, polycrystalline silicon/silicide, TaN/Cu, TaN/Co and TaN/Ru, or the conductive film 120 can be selected from the group consisting of the above materials.

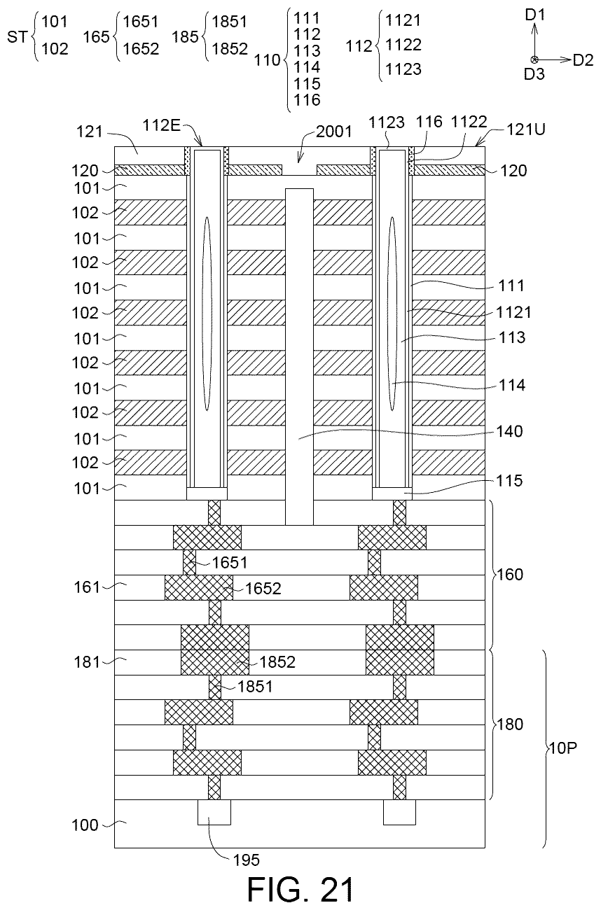

FIG. 21 illustrates a schematic view of a structure at a stage of the method for manufacturing the semiconductor device. An insulating material layer 121 is formed on the conductive film 120. The insulating material layer 121 may cover the conductive film 120 and fill the opening 2001. The insulating material layer 121 may not cover the terminal surface 112E of the channel layer 112. An upper surface of the insulating material layer 121 may be coplanar with the terminal surface 112E of the channel layer 112. The insulating material layer 121 may include an insulating material including oxide. In some embodiment, the insulating material layer 121 includes silicon oxide. In some embodiment, a deposition process and a polishing process are performed to form the insulating material layer 121 on the conductive film 120 and in the opening 2001, and expose the terminal surface 112E of the channel layer 112.

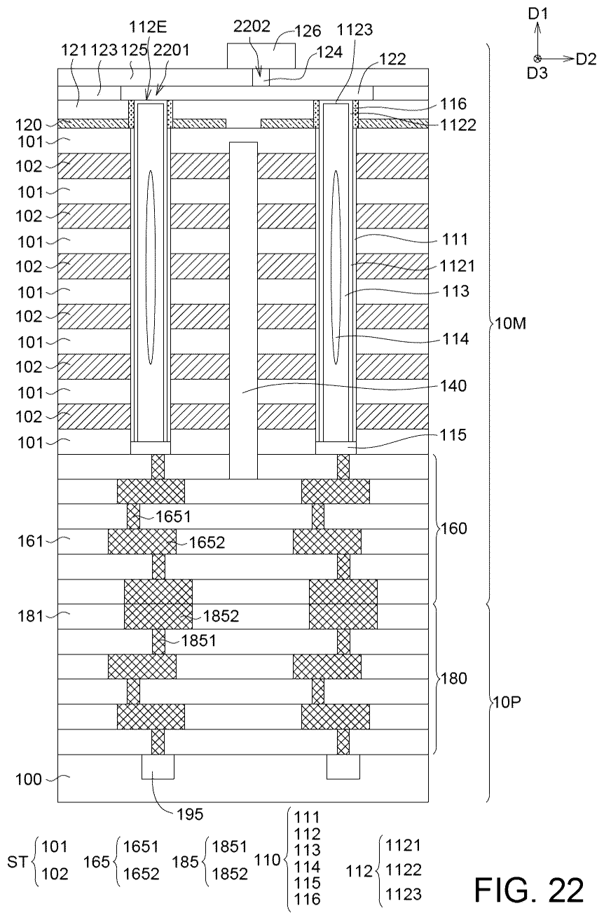

FIG. 22 illustrates a schematic view of a structure at a stage of the method for manufacturing the semiconductor device. An insulating material layer 123, a conductive structure 122 in the insulating material layer 123, an insulating material layer 125, a via element 124 in the insulating material layer 125, and a conductive element 126 on the insulating material layer 125 are formed. The conductive structure 122 may contact the terminal surface 112E of the channel layer 112. The insulating material layer 121, the insulating material layer 123 and the insulating material layer 125 may include the same or different materials. The insulating material layer 123 and the insulating material layer 125 may include insulating materials including oxide. In some embodiment, the insulating material layer 123 and the insulating material layer 125 include silicon oxide. The conductive structure 122 may include a conductive material, and the conductive material includes, but is not limited to, doped or undoped polycrystalline silicon, metal, and the combinations thereof. In some embodiment, the conductive structure 122 includes N-type doped polycrystalline silicon. The via element 124 and the conductive element 126 may include the same or different materials. The via element 124 and the conductive element 126 may include conductive materials, and the conductive materials include, but is not limited to, doped or undoped polycrystalline silicon, metal, and the combinations thereof. In some embodiment, the via element 124 and the conductive element 126 may include TiN, TaN, Ti, Ta, Cu, Al, Ag, W, Ir, Ru, Pt and combinations thereof. In some embodiments, the via element 124 includes N-type doped polycrystalline silicon.

In some embodiments, the insulating material layer 123 is formed on the insulating material layer 121 and the conductive film 120 through a deposition process, a hole 2201 is formed in the insulating material layer 123 through an etching process, and then the conductive structure 122 is formed in the hole 2201 through a deposition process. In some embodiments, the insulating material layer 125 is formed on the insulating material layer 123 and the conductive structure 122 through a deposition process, a groove 2202 is formed in the insulating material layer 125 through an etching process, and then the via element 124 is formed in the groove 2202 through a deposition process. In some embodiments, the conductive element 126 is formed on the insulating material layer 125 and the via element 124 through a patterning process.

In some embodiments, through the method schematically illustrated in FIGS. 3 to 22, a semiconductor device 10 as shown FIG. 1 is provided.

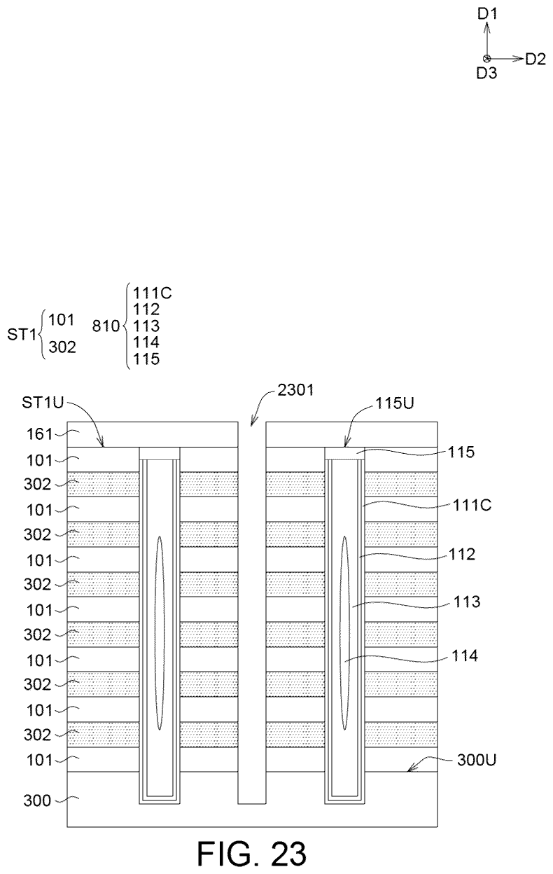

FIG. 23 to FIG. 36 illustrate schematic cross-sectional views of various stages of a method for manufacturing a semiconductor device according to some embodiments of the present disclosure. In an embodiment, the manufacturing steps illustrated with reference to FIGS. 23 to 36 can be performed after the manufacturing steps illustrated with reference to FIGS. 3 to 8.

FIG. 23 illustrates a schematic view of a structure at a stage of the method for manufacturing the semiconductor device. An insulating material layer 161 is formed on the insulating stack structure ST1. An opening 2301 is formed in the insulating stack structure ST1. The opening 2301 extends along the first direction D1, penetrates the insulating stack structure ST1 and the insulating material layer 161, and stop at the substrate 300. A bottom of the opening 2301 can be lower than the upper surface 300U of the substrate 300 in the first direction D1. The opening 2301 may be between the pillar structures 810. A sidewall of the insulating material layer 161, a sidewall of the insulating stack structure ST1, and the substrate 300 are exposed by the opening 2301. In some embodiments, the insulating material layer 161 is formed on the upper surface ST1U of the insulating stack structure ST1; a portion of the insulating material layer 161, a portion of the insulating layers 101, a portion of the insulating layers 302 and a portion of the substrate 300 are removed through an etching process to form the opening 2301.

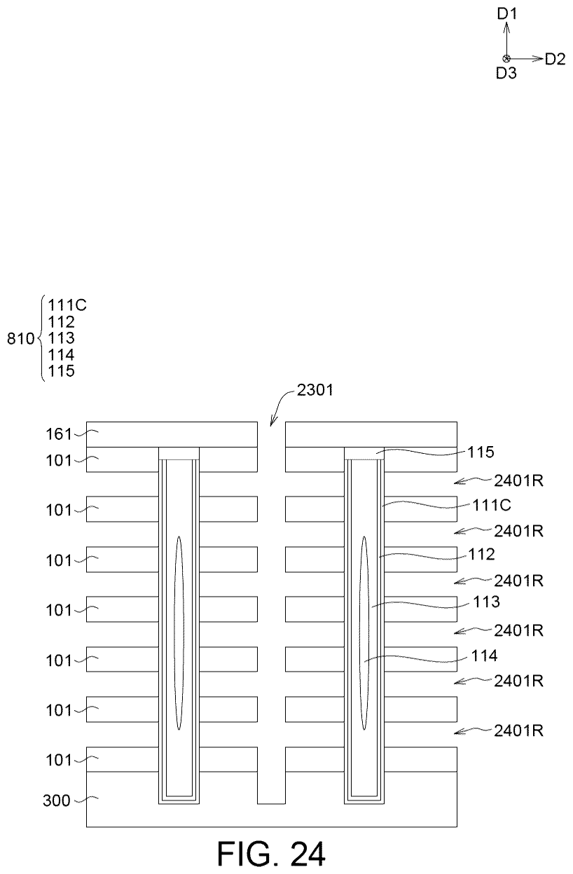

FIG. 24 illustrates a schematic view of a structure at a stage of the method for manufacturing the semiconductor device. Spaces 2401R are formed. The spaces 2401R are between the insulating layers 101. The spaces 2401R can be connected to the opening 2301. The upper surfaces of the insulating layers 101, the lower surfaces of the insulating layers 101, and a portion of an outer sidewalls of the memory layers 111C of the pillar structures 810 are exposed by the spaces 2401R. In some embodiments, the insulating layers 302 between the insulating layers 101 are removed through a selectively etching process to form the spaces 2401R, and the insulating layers 101, the insulating material layer 161, the pillar structures 810 and the substrate 300 are retained. The selectively etching process can be performed through the opening 2401. During this stage, the pillar structures 810 may serve as structural support.

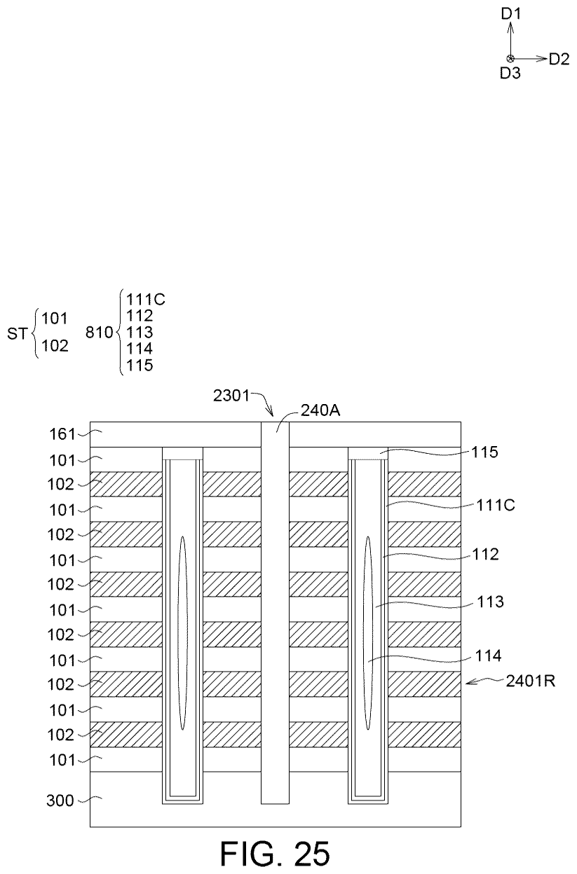

FIG. 25 illustrates a schematic view of a structure at a stage of the method for manufacturing the semiconductor device. A stack structure ST including conductive layers 102 and the insulating layers 101, and an isolation layer 240A in the stack structure ST are formed. The isolation layer 240A extends along the first direction D1 and penetrates the stack structure ST, the insulating material layer 161 and the substrate 300. The isolation layer 240A may be between the pillar structures 810. The isolation layer 240A may include an insulating material including oxide. In some embodiment, the isolation layer 240A includes silicon oxide. In some embodiment, the spaces 2401R is filled with the conductive layers 102 through a deposition process to form the stack structure ST; the opening 2301 is filled with the isolation layer 240A through a deposition process.

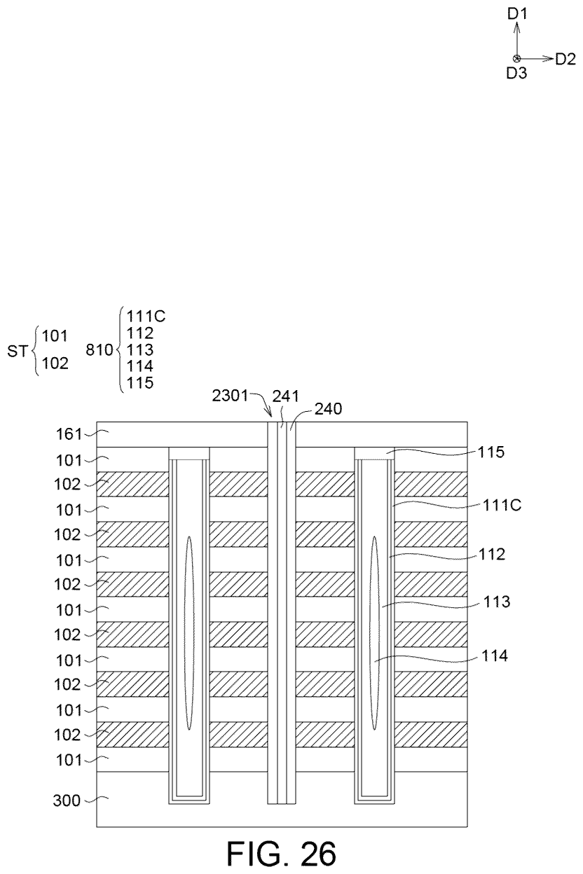

FIG. 26 illustrates a schematic view of a structure at a stage of the method for manufacturing the semiconductor device. A conductive strip 241 and an isolation layer 240 are formed. The conductive strip 241 and an isolation layer 240 ate in the opening 2301. The conductive strip 241 may include a conductive material, and the conductive material includes, but is not limited to, doped or undoped polycrystalline silicon, metal, and the combinations thereof. In some embodiment, the conductive strip 241 includes TiN, TaN, Ti, Ta, Cu, Al, Ag, W, Ir, Ru, Pt and combinations thereof. In some embodiments, a portion of the isolation layer 240A is removed through an etching process to form a trench, and a portion of the isolation layer 240A is retained; the retained portion of the isolation layer 240A is the isolation layer 240; the conductive strip 241 is then formed in the trench through a deposition process.

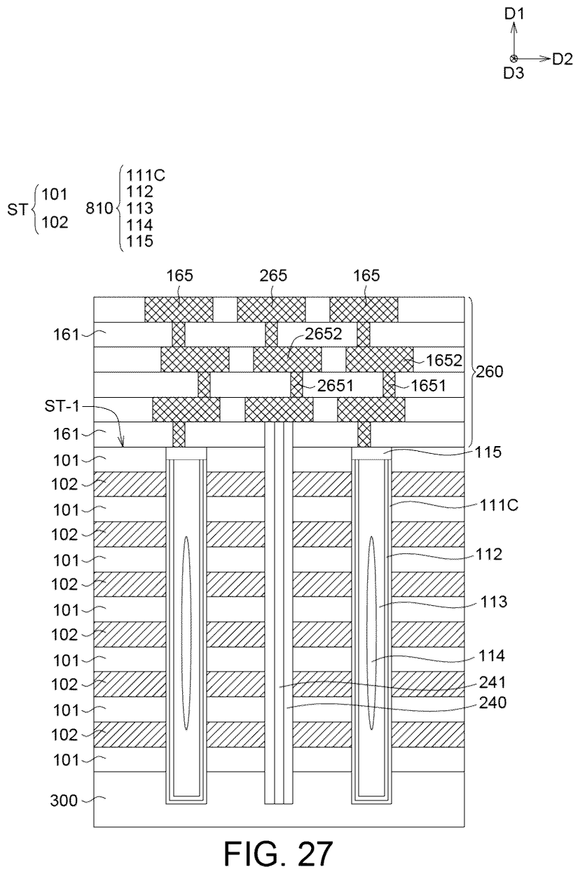

FIG. 27 illustrates a schematic view of a structure at a stage of the method for manufacturing the semiconductor device. An interconnection structure 260 is formed on an surface ST-1 of the stack structure ST. The interconnection structure 260 includes insulating material layers 161, conductive interconnections 165 in the insulating material layers 161, and a conductive interconnection 265 in the insulating material layers 161. Two conductive interconnections 165 correspond to different pillar structures 810. Two conductive interconnections 165 are electrically connected to different pillar structures 810. The conductive interconnection 265 corresponds to the conductive strip 241. The conductive interconnection 265 is electrically connected to the conductive strip 241. The conductive interconnection 265 includes via elements 2651 and conductive elements 2652. The via elements 2651 and the conductive elements 2652 may include the same or different materials. The via elements 2651 and the conductive elements 2652 may include conductive materials, and the conductive materials include, but is not limited to, metal. For example, the via elements 2651 and the conductive elements 2652 may include TiN, TaN, Ti, Ta, Cu, Al, Ag, W, Ir, Ru, Pt and combinations thereof. In some embodiments, the via elements 2651 and the conductive elements 2652 include Cu. In some embodiments, the insulating material layer 161 is formed through a deposition process, grooves can be formed in the insulating material layer 161 through a patterning process, the position of the grooves is the position where the via element(s) 1651 and/or the conductive element(s) 1652 and/or the via element(s) 2651 and/or the conductive element(s) 2652 will be formed, and then the grooves are filled with the material of the via element 1651 and/or the material of the conductive element 1652 and/or the material of the via element(s) 2651 and/or the material of the conductive element(s) 2652 to form the via element(s) 1651 and/or the conductive element(s) 1652 and/or the via element(s) 2651 and/or the conductive element(s) 2652 in the insulating material layer 161; the above steps can be repeated until the configurations of the conductive interconnection 165 and the conductive interconnection 265 meet the requirements. In some embodiments, the interconnection structure 260 can be understood as a memory array interconnection structure. The conductive elements 1652 and the conductive element 2652 in the insulating material layer 161 that are farthest from the pillar structures 810 in the first direction D1 can be understood as bonding layers, and the bonding layers can be used to bond to other structures.

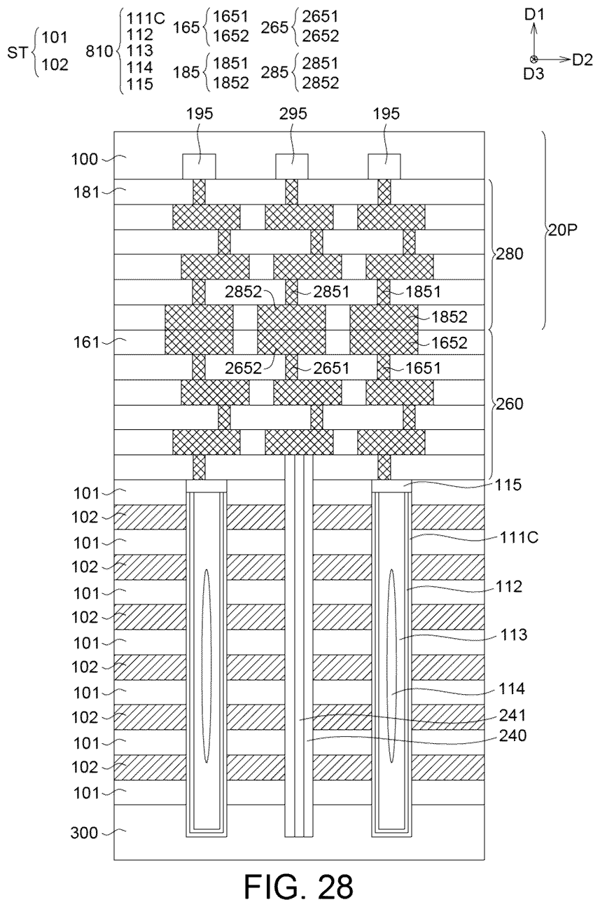

FIG. 28 illustrates a schematic view of a structure at a stage of the method for manufacturing the semiconductor device. A semiconductor structure 20P is provided. The semiconductor structure 20P is bonded to the interconnection structure 260. The semiconductor structure 20P includes a substrate 100, semiconductor elements 195 in the substrate 100, a semiconductor element 295 in the substrate 100, and an interconnection structure 280 on the substrate 100, the semiconductor elements 195 and the semiconductor element 295. The interconnection structure 280 may include insulating material layers 181, conductive interconnections 185 in the insulating material layers 181 and a conductive interconnection 285 in the insulating material layers 181. The conductive interconnections 185 are electrically connected to different semiconductor elements 195. The conductive interconnection 285 are electrically connected to different semiconductor element 295. The conductive interconnections 285 includes via elements 2851 and conductive elements 2852. The via elements 2851 and the conductive elements 2852 may include the same or different materials. The via elements 2851 and the conductive elements 2852 may include conductive materials, and the conductive materials include, but are not limited to, metal. For example, the via elements 2851 and the conductive elements 2852 may include TiN, TaN, Ti, Ta, Cu, Al, Ag, W, Ir, Ru, Pt and combinations thereof. In some embodiments, the via elements 2851 and the conductive elements 2852 include Cu. The conductive elements 1852 and the conductive element 2852 in the insulating material layer 181 that are farthest from the substrate 100 in the first direction D1 can be understood as bonding layers, and the bonding layers can be used to bond to other structures (e.g. the interconnection structure 260). The method for manufacturing the interconnection structure 280 may be similar to the method for manufacturing the interconnection structure 260 or the method for manufacturing the interconnection structure 180. In some embodiments, a solid state bonding technology such as a diffusion bonding technology can be used to bond the bonding layers (the conductive elements 1852 and the conductive element 2852) of the interconnection structure 280 of the semiconductor structure 20P to the bonding layers (the conductive elements 1652 and the conductive element 2652) of the interconnection structure 260. The bonding of the semiconductor structure 20P and the interconnection structure 260 may be a Cu—Cu hybrid bonding.

After the semiconductor structure 20P is bonded to the interconnection structure 260, the conductive interconnections 185 of the semiconductor structure 20P can be electrically connected to different conductive interconnections 165 of the interconnection structure 260, the conductive interconnection 285 of the semiconductor structure 20P can be electrically connected to different conductive interconnections 265 of the interconnection structure 260. Thus, the semiconductor element 195 can be electrically connected to the pillar structure 810 through a corresponding conductive interconnection 185, and a corresponding conductive interconnection 165, and the semiconductor element 295 can be electrically connected to the conductive strip 241 through the conductive interconnection 285, and the conductive interconnection 265.

In some embodiments, the interconnection structure 280 can be a middle-end-of-line (MEOL) interconnection structure or a back-end-of-line (BEOL) interconnection structure.

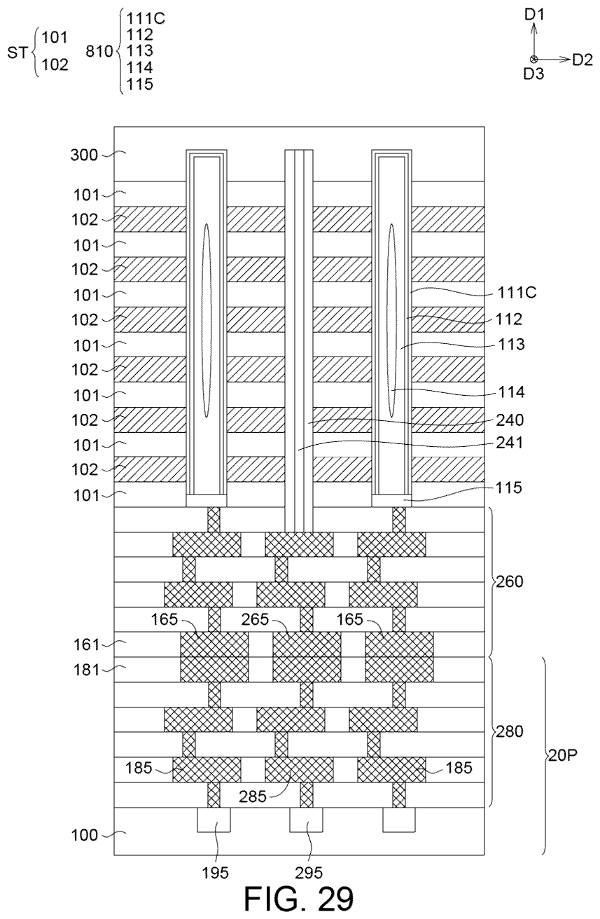

FIG. 29 illustrates a schematic view of a structure at a stage of the method for manufacturing the semiconductor device. The structure shown in FIG. 28 is rotated. After the rotation, the substrate 300 is above the substrate 100. In some embodiments, the manufacturing method may omit the rotation step.

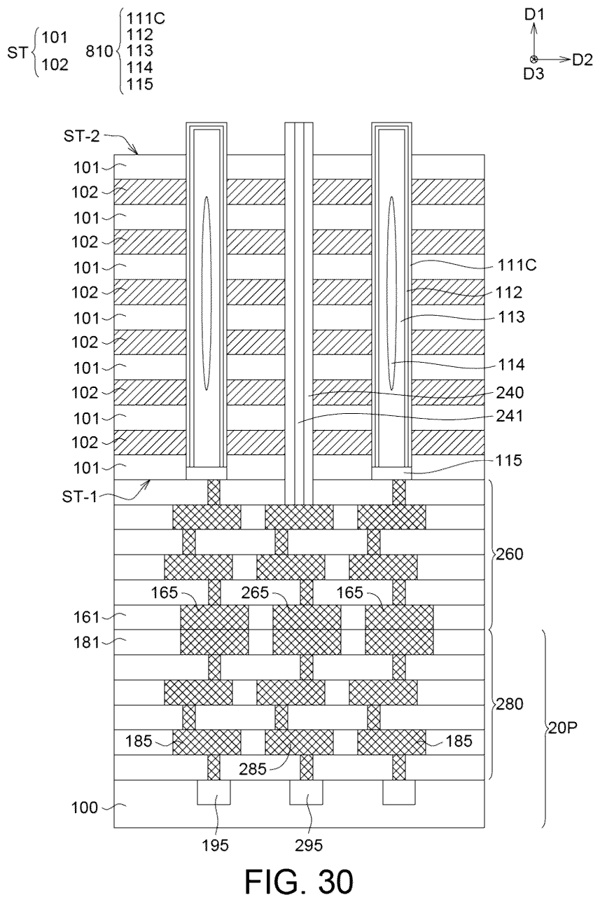

FIG. 30 illustrates a schematic view of a structure at a stage of the method for manufacturing the semiconductor device. A portion of the pillar structures 810, a portion of the conductive strip 241 and a portion of the isolation layer 240 are exposed. In some embodiments, the substrate 300 is removed through an etching process to expose the portion of the pillar structures 810 that was previously in the substrate 300 and the portions of the conductive strip 241 and the isolation layer 240 that was previously in the substrate 300, and expose the surface ST-2 of the stack structure ST. The surface ST-2 of the stack structure ST is opposite to the surface ST-1 of the stack structure ST.

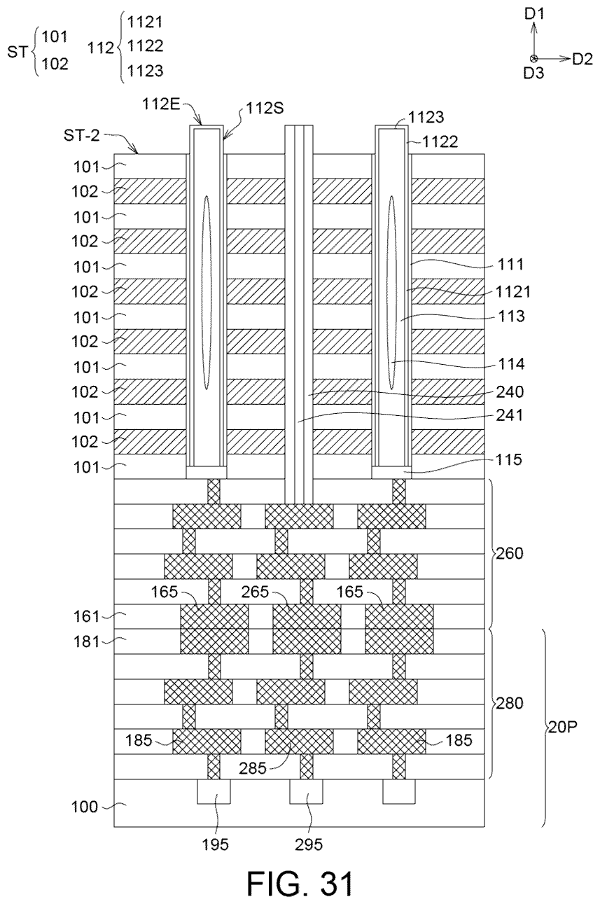

FIG. 31 illustrates a schematic view of a structure at a stage of the method for manufacturing the semiconductor device. A memory layer 111 is formed. A portion of the channel layer 112 is exposed. In some embodiments, a portion of the memory layer 111C is removed through an etching process to expose the second channel portion 1122 and the third channel portion 1123 of the channel 112, and a portion of the memory layer 111C in the stack structure ST is retained. The portion of the memory layer 111C in the stack structure ST is the memory layer 111. Removing a portion of the memory layer 111C exposes a portion of a sidewall 112S of the channel layer 112 and a terminal surface 112E of the channel layer 112.

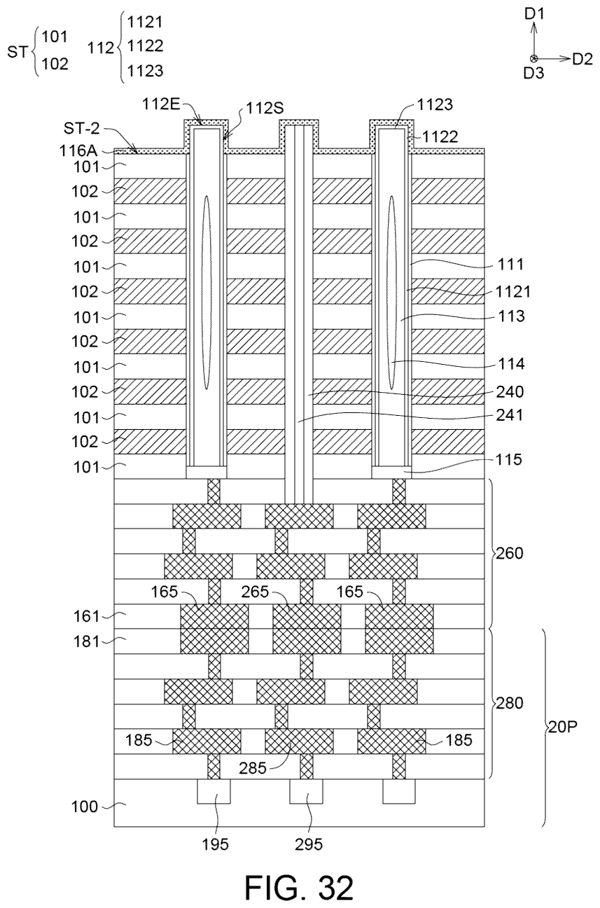

FIG. 32 illustrates a schematic view of a structure at a stage of the method for manufacturing the semiconductor device. A dielectric layer 116A is formed on the stack structure ST and the channel layer 112. In some embodiments, the dielectric layer 116A is formed on the surface ST-2 of the stack structure ST, the exposed sidewall 112S of the channel layer 112, the exposed terminal surface 112E of the channel layer 112, the exposed conductive strip 241 and the exposed isolation layer 240 through a deposition process.

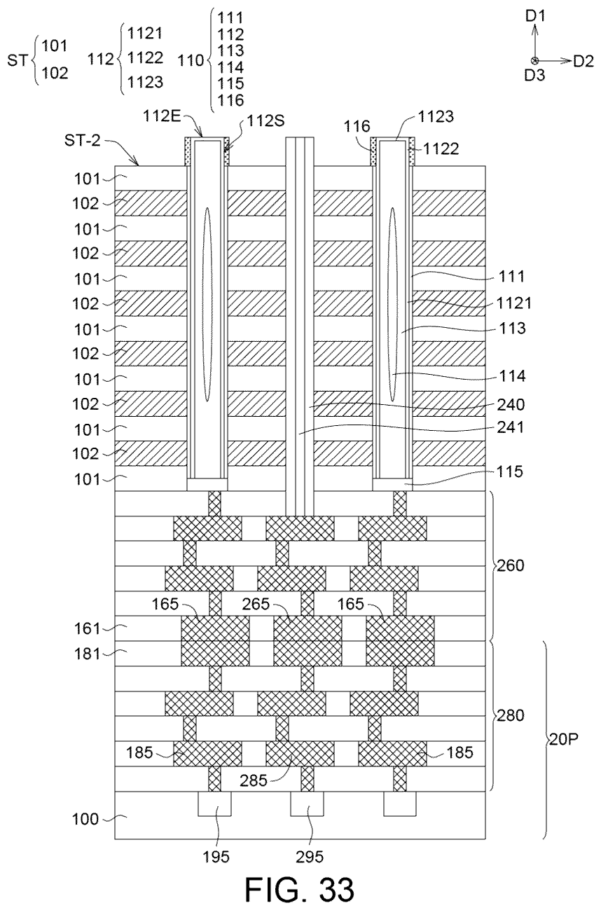

FIG. 33 illustrates a schematic view of a structure at a stage of the method for manufacturing the semiconductor device. A dielectric layer 116 is formed. The dielectric layer 116 is formed on the sidewall 112S of the channel layer 112. A width of the dielectric layer 116 in the second direction D2 may be smaller than a width of the memory layer 111 in the second direction D2. In some embodiments, a portion of the dielectric layer 116A on the surface ST-2 of the stack structure ST, a portion of the dielectric layer 116A on the terminal surface 112E of the channel layer 112, a portion of the dielectric layer 116A on the conductive strip 241 and the isolation layer 240 are removed through an etching process to expose the surface ST-2 of the stack structure ST, the terminal surface 112E of the channel layer 112, the conductive strip 241 and the isolation layer 240, and a portion of the dielectric layer 116A on the sidewall 112S of the channel layer 112 is retained. The retained portion of the dielectric layer 116A is the dielectric layer 116. Therefore, a pillar element 110 including the memory layer 111, the channel layer 112, the insulating film 113, the air gap 114, the pad 115 and the dielectric layer 116 is formed. In other embodiments, the dielectric layer 116 can be formed through oxidation process illustrated with reference to FIG. 16.

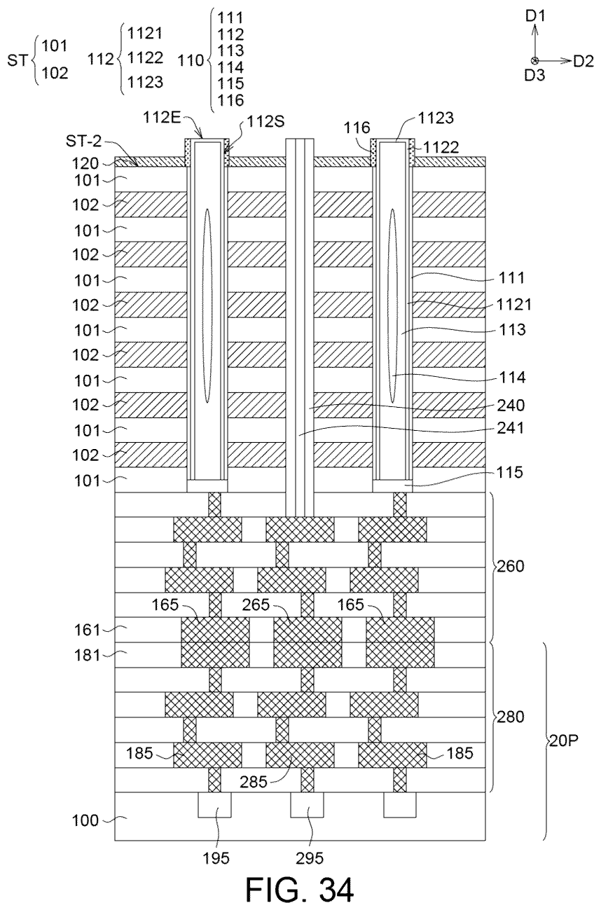

FIG. 34 illustrates a schematic view of a structure at a stage of the method for manufacturing the semiconductor device. A conductive film 120 is formed. In some embodiments, the conductive film 120 is formed on the surface ST-2 of the stack structure ST through a deposition process and an etching process.

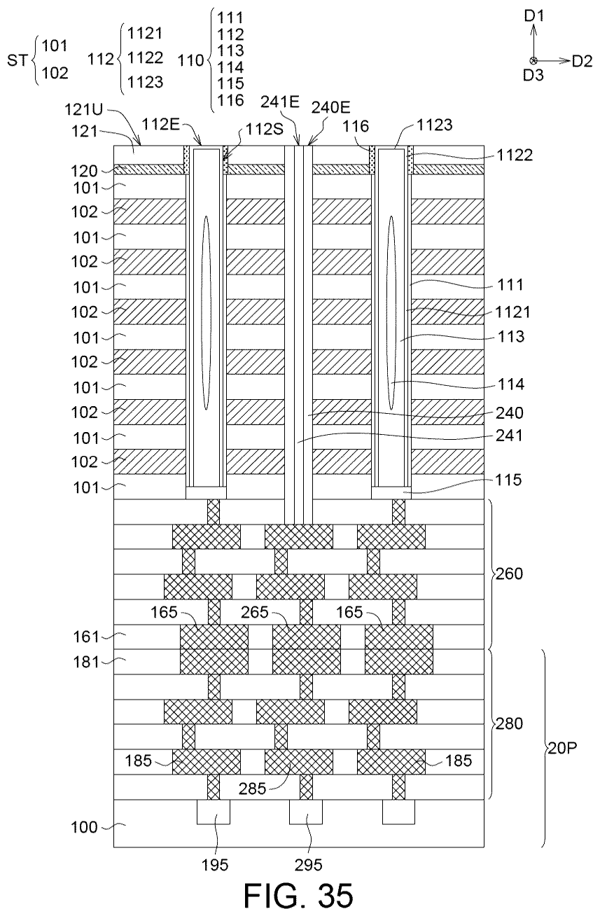

FIG. 35 illustrates a schematic view of a structure at a stage of the method for manufacturing the semiconductor device. An insulating material layer 121 is formed on the conductive film 120. The insulating material layer 121 may cover the conductive film 120. The insulating material layer 121 may not cover the terminal surface 112E of the channel layer 112, a terminal surface 241E of the conductive strip 241 and a terminal surface 240E of the isolation layer 240. An upper surface 121U of the insulating material layer 121, the terminal surface 112E of the channel layer 112, the terminal surface 241E of the conductive strip 241 and the terminal surface 240E of the isolation layer 240 may be coplanar. In some embodiment, a deposition process and a polishing process are performed to form the insulating material layer 121 on the conductive film 120, and expose the terminal surface 112E of the channel layer 112, the terminal surface 241E of the conductive strip 241 and the terminal surface 240E of the isolation layer 240.

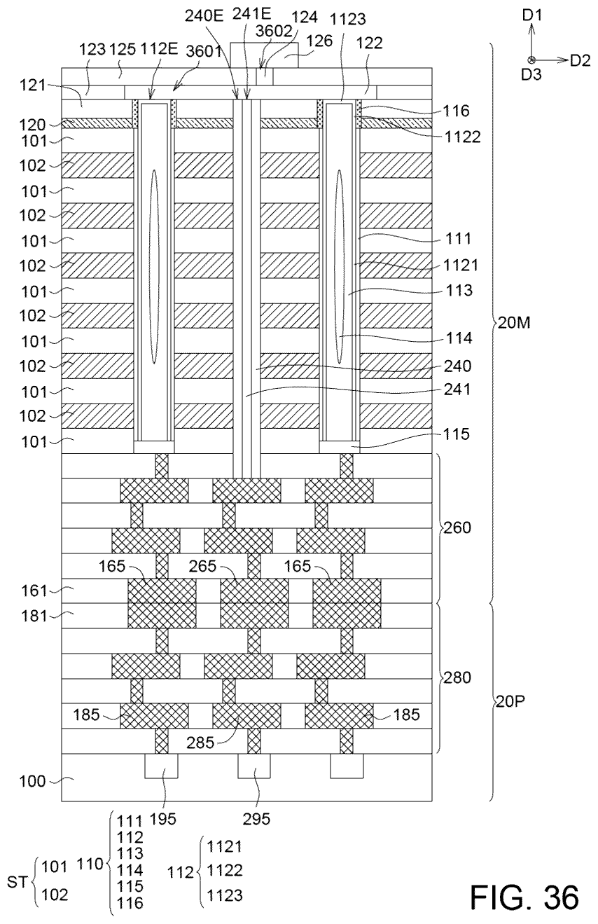

FIG. 36 illustrates a schematic view of a structure at a stage of the method for manufacturing the semiconductor device. An insulating material layer 123, a conductive structure 122 in the insulating material layer 123, an insulating material layer 125, a via element 124 in the insulating material layer 125, and a conductive element 126 on the insulating material layer 125 are formed. The conductive structure 122 may contact the terminal surface 112E of the channel layer 112, the terminal surface 241E of the conductive strip 241 and the terminal surface 240E of the isolation layer 240. In some embodiments, the insulating material layer 123 is formed on the insulating material layer 121 and the conductive film 120 through a deposition process, a hole 3601 is formed in the insulating material layer 123 through an etching process, and then the conductive structure 122 is formed in the hole 3601 through a deposition process. In some embodiments, the insulating material layer 125 is formed on the insulating material layer 123 and the conductive structure 122 through a deposition process, a groove 3602 is formed in the insulating material layer 125 through an etching process, and then the via element 124 is formed in the groove 3602 through a deposition process. In some embodiments, the conductive element 126 is formed on the insulating material layer 125 and the via element 124 through a patterning process.

In some embodiments, through the method schematically illustrated in FIGS. 23 to 36, a semiconductor device 20 as shown FIG. 2 is provided.

According to embodiments of the present disclosure, the semiconductor device and the method for manufacturing the same of the present disclosure use a dielectric layer (such as the dielectric layer 116) as the gate dielectric layer of the ground select line switch, the dielectric layer and the memory layer include different materials. With such a configuration, the voltage Vt of ground select line will be different from the voltage of the memory cell and therefore disturbance problems (e.g. a read disturbance problem, a program disturbance problem and a erase disturbance problem) can be reduced or avoided, and the electrical performance of the semiconductor devices can be improved. In a comparative example of a semiconductor device, the gate dielectric layer of the ground select line switch includes the same material as the memory layer. In such comparative example, it is easily to be disturbed during program operation and/or erase operation because the voltage Vt of ground select line will be modified to be the same as the voltage of the memory cell.

It is noted that the structures and methods as described above are provided for illustration. The disclosure is not limited to the configurations and procedures disclosed above. Other embodiments with different configurations of known elements can be applicable, and the exemplified structures could be adjusted and changed based on the actual needs of the practical applications. It is, of course, noted that the configurations of figures are depicted only for demonstration, not for limitation. Thus, it is known by people skilled in the art that the related elements and layers in a semiconductor structure, the shapes or positional relationship of the elements and the procedure details could be adjusted or changed according to the actual requirements and/or manufacturing steps of the practical applications.

While the disclosure has been described by way of example and in terms of the exemplary embodiment(s), it is to be understood that the disclosure is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A semiconductor device, comprising:
a substrate;
a stack structure on the substrate;
an interconnection structure between the substrate and the stack structure; and
a pillar element penetrating the stack structure and comprising:
a channel layer;
a memory layer surrounding the channel layer; and
a dielectric layer surrounding the channel layer, wherein the dielectric layer and the memory layer comprise different materials.

2. The semiconductor device according to claim 1, wherein the pillar element comprises an insulating film and a pad, the channel layer surrounds the insulating film, the pad is between the insulating film and the interconnection structure, and the memory layer is connected between the dielectric layer and the pad.

3. The semiconductor device according to claim 2, wherein the channel layer and the insulating film extend beyond the stack structure, the memory layer and the pad are in the stack structure, and the dielectric layer is on the stack structure.

4. The semiconductor device according to claim 1, further comprising a conductive structure on the stack structure, wherein the channel layer is electrically connected between the conductive structure and the interconnection structure.

5. The semiconductor device according to claim 4, wherein the pillar element comprises an insulating film, the channel layer comprises a first channel portion, a second channel portion and a third channel portion, the second channel portion is between the first channel portion and the third channel portion, the first channel portion is between the insulating film and the memory layer, the second channel portion is between the insulating film and the dielectric layer, and the third channel portion covers an end of the insulating film and is between the insulating film and the conductive structure.

6. The semiconductor device according to claim 4, wherein the semiconductor device comprises a plurality of the pillar elements, and the conductive structure is electrically connected to the pillar elements.

7. The semiconductor device according to claim 4, further comprising a conductive strip penetrating the stack structure and electrically connected between the conductive structure and the interconnection structure.

8. The semiconductor device according to claim 1, further comprising a conductive film on the stack structure and surrounding the dielectric layer.

9. The semiconductor device according to claim 8, wherein the semiconductor device comprises memory cells defined in the memory layer, and the conductive film is functioned as a ground select line (GSL) for the memory cells.

10. The semiconductor device according to claim 9, wherein the stack structure comprises conductive layers surrounding the memory layer and functioned as word lines for the memory cells, and the conductive film and the conductive layers comprise different materials.

11. The semiconductor device according to claim 1, further comprising a conductive strip penetrating the stack structure.

12. The semiconductor device according to claim 11, further comprising an isolation layer isolated the conductive strip from the stack structure.

13. The semiconductor device according to claim 11, further comprising a conductive structure on the stack structure and electrically connected to the conductive strip.

14. A method for manufacturing a semiconductor device, comprising:
forming a stack structure on a substrate;
forming a channel layer penetrating the stack structure;
forming an interconnection structure on a first surface of the stack structure;
forming a memory layer penetrating the stack structure and surrounding the channel layer;
forming a dielectric layer on a sidewall of the channel layer, wherein the dielectric layer and the memory layer comprise different materials; and
forming a conductive film on a second surface of the stack structure, wherein the second surface is opposite to the first surface.

15. The method according to claim 14, further comprising:
providing a semiconductor element and another interconnection structure on the semiconductor element;
bonding the interconnection structure to the another interconnection structure.

16. The method according to claim 14, wherein the conductive film surrounds the dielectric layer, and a terminal surface of the memory layer is lower than a terminal surface of the channel layer.

17. The method according to claim 14, further comprising:
forming a conductive structure on the second surface of the stack structure, wherein the channel layer is electrically connected between the interconnection structure and the conductive structure

18. The method according to claim 17, wherein the dielectric layer is connected between the memory layer and the conductive structure, and the conductive film is on a sidewall of the dielectric layer.

19. The method according to claim 14, wherein forming the dielectric layer on the sidewall of the channel layer comprises performing an oxidation process to convert a portion of the channel layer to an oxidized portion.

20. The method according to claim 14, further comprising:
forming an opening penetrating the stack structure;
forming a conductive strip and an isolation layer in the opening, wherein the isolation layer isolated the conductive strip from the stack structure.
